(19) United States
(12) Patent Application Publication
(10) Pub. No.: US 2026/0040580 A1
(43) Pub. Date: Feb. 5, 2026

(54) MEMORY DEVICE

(71) Applicant: Kioxia Corporation, Tokyo (JP)

(72) Inventor: Shinya ARAI, Yokkaichi (JP)

(73) Assignee: Kioxia Corporation, Tokyo (JP)

(21) Appl. No.: 19/069,774

(22) Filed: Mar. 4, 2025

(30) Foreign Application Priority Data
Aug. 1, 2024 (JP) 2024-126092

(51) Int. Cl. H10B 80/00; H01L 23/00; H01L 25/00; H01L 25/065; H01L 25/18

(52) U.S. Cl. CPC H10B 80/00; H01L 24/08; H01L 25/0657; H01L 25/18; H01L 25/50; H01L 2224/08145; H01L 2924/1431; H01L 2924/14511

(57) ABSTRACT

A memory device according to an embodiment includes a bonding surface. The memory device includes a substrate, first and second circuit layers, and a wiring layer. The substrate has first and second areas. The first circuit layer includes a CMOS circuit. The second circuit layer is provided above the bonding surface. The wiring layer is provided above the second circuit layer. The wiring layer includes a pad electrically connected to the CMOS circuit via the second circuit layer. The second circuit layer includes a layer stack. The layer stack includes, in the first area, first insulating layers and first conductive layers alternately stacked and includes, in the second area, the first insulating layers and the first conductive layers or first members alternately stacked. The pad has a portion overlapping with the layer stack and does not have a portion overlapping with a source line.

### CROSS-REFERENCE TO RELATED APPLICATION

This application is based upon and claims the benefit of priority from Japanese Patent Application No. 2024-126092, filed Aug. 1, 2024, the entire contents of which are incorporated herein by reference.

### FIELD

Embodiments described herein relate generally to a memory device.

### BACKGROUND

A NAND flash memory capable of storing data in a nonvolatile manner is known.

### BRIEF DESCRIPTION OF DRAWINGS

FIG. 1 is a block diagram showing an example of an overall configuration of a memory system including a memory device according to a first embodiment.

FIG. 2 is a circuit diagram showing an example of a circuit configuration of a memory cell array included in the memory device according to the first embodiment.

FIG. 3 is a perspective view showing an example of an external appearance of the memory device according to the first embodiment.

FIG. 4 is a plan view showing an example of a planar layout of the memory device according to the first embodiment.

FIG. 5 is a plan view showing an example of a planar layout in a core area of the memory cell array included in the memory device according to the first embodiment.

FIG. 6 is a cross-sectional view taken along line VI-VI of FIG. 5, showing an example of a cross-sectional structure in a storage area of the memory cell array included in the memory device according to the first embodiment.

FIG. 7 is a cross-sectional view taken along line VII-VII of FIG. 6, showing an example of a cross-sectional structure of a memory pillar included in the memory device according to the first embodiment.

FIG. 8 is a cross-sectional view showing an example of a cross-sectional structure of the memory device according to the first embodiment.

FIG. 9 is a plan view showing an example of a planar layout of a wiring layer in the memory device according to the first embodiment.

FIG. 10 is a plan view showing an example of a planar layout of the vicinity of a pad unit in the memory device according to the first embodiment.

FIG. 11 is a cross-sectional view taken along line XI-XI of FIG. 10, showing an example of a cross-sectional structure of the vicinity of the pad unit in the memory device according to the first embodiment.

FIG. 12 is a flowchart showing an example of a method of manufacturing the memory device according to the first embodiment.

FIGS. 13, 14, 15, 16, and 17 are cross-sectional views showing examples of cross-sectional structures in the manufacturing process of the memory device according to the first embodiment.

FIG. 18 is a plan view showing an example of a planar layout of the vicinity of a pad unit in a memory device according to a first comparative example.

FIG. 19 is a cross-sectional view taken along line XIX-XIX of FIG. 18, showing an example of a cross-sectional structure of the vicinity of the pad unit in the memory device according to the first comparative example.

FIG. 20 is a plan view showing an example of a planar layout of the vicinity of a pad unit in a memory device according to a second comparative example.

FIG. 21 is a cross-sectional view taken along line XXI-XXI of FIG. 20, showing an example of a cross-sectional structure of the vicinity of the pad unit in the memory device according to the second comparative example.

FIG. 22 is a plan view showing an example of a planar layout of the vicinity of a pad unit in a memory device according to a second embodiment.

FIG. 23 is a cross-sectional view taken along line XXIII-XXIII of FIG. 22, showing an example of a cross-sectional structure of the vicinity of the pad unit in the memory device according to the second embodiment.

FIG. 24 is a flowchart showing an example of a method of manufacturing the memory device according to the second embodiment.

FIGS. 25, 26, and 27 are cross-sectional views showing examples of cross-sectional structures in the manufacturing process of the memory device according to the second embodiment.

FIG. 28 is a plan view showing an example of a planar layout of the vicinity of a pad unit in a memory device according to a third embodiment.

FIG. 29 is a cross-sectional view taken along line XXIX-XXIX of FIG. 28, showing an example of a cross-sectional structure of the vicinity of the pad unit in the memory device according to the third embodiment.

FIG. 30 is a flowchart showing an example of a method of manufacturing the memory device according to the third embodiment.

FIGS. 31, 32, 33, and 34 are cross-sectional views showing examples of cross-sectional structures in the manufacturing process of the memory device according to the third embodiment.

FIG. 35 is a plan view showing an example of a planar layout of the vicinity of a pad unit in a memory device according to a fourth embodiment.

FIG. 36 is a cross-sectional view taken along line XXXVI-XXXVI of FIG. 35, showing an example of a cross-sectional structure of the vicinity of the pad unit in the memory device according to the fourth embodiment.

FIG. 37 is a plan view showing an example of a planar layout of the vicinity of a pad unit in a memory device according to a fifth embodiment.

FIG. 38 is a cross-sectional view taken along line XXXVIII-XXXVIII of FIG. 37, showing an example of a cross-sectional structure of the vicinity of the pad unit in the memory device according to the fifth embodiment.

FIG. 39 is a cross-sectional view showing an example of a cross-sectional structure of a memory cell array included in a memory device according to a sixth embodiment.

FIG. 40 is a plan view showing an example of a planar layout of the vicinity of a pad unit in the memory device according to the sixth embodiment.

FIG. 41 is a cross-sectional view taken along line XLI-XLI of FIG. 40, showing an example of a cross-sectional structure of the vicinity of the pad unit in the memory device according to the sixth embodiment.

FIG. 42 is a flowchart showing an example of a method of manufacturing the memory device according to the sixth embodiment.

FIGS. 43 and 44 are cross-sectional views showing examples of cross-sectional structures in the manufacturing process of the memory device according to the sixth embodiment.

FIG. 45 is a plan view showing an example of a planar layout of the vicinity of a pad unit in a memory device according to a seventh embodiment.

FIG. 46 is a cross-sectional view taken along line XLVI-XLVI of FIG. 45, showing an example of a cross-sectional structure of the vicinity of the pad unit in the memory device according to the seventh embodiment.

FIG. 47 is a plan view showing an example of a planar layout of the vicinity of a pad unit in a memory device according to an eighth embodiment.

FIG. 48 is a cross-sectional view taken along line XLVIII-XLVIII of FIG. 47, showing an example of a cross-sectional structure of the vicinity of the pad unit in the memory device according to the eighth embodiment.

FIG. 49 is a plan view showing an example of a planar layout of the vicinity of a pad unit in a memory device according to a ninth embodiment.

FIG. 50 is a cross-sectional view taken along line L-L of FIG. 49, showing an example of a cross-sectional structure of the vicinity of the pad unit in the memory device according to the ninth embodiment.

FIG. 51 is a plan view showing an example of a planar layout of the vicinity of a pad unit in a memory device according to a tenth embodiment.

FIG. 52 is a cross-sectional view taken along line LII-LII of FIG. 51, showing an example of a cross-sectional structure of the vicinity of the pad unit in the memory device according to the tenth embodiment.

FIG. 53 is a plan view showing an example of a planar layout of the vicinity of a pad unit in a memory device according to an eleventh embodiment.

FIG. 54 is a cross-sectional view taken along line LIV-LIV of FIG. 53, showing an example of a cross-sectional structure of the vicinity of the pad unit in the memory device according to the eleventh embodiment.

FIG. 55 is a cross-sectional view showing an example of a detailed cross-sectional structure of the vicinity of two bonding pads arranged to face each other in the memory device according to the embodiments.

### DETAILED DESCRIPTION

In general, according to one embodiment, a memory device includes a bonding surface. The memory device includes a substrate, a first circuit layer, a second circuit layer, and a wiring layer. The substrate has a first area and a second area arranged in a first direction. The first circuit layer is provided between the substrate and the bonding surface and includes a CMOS circuit. The second circuit layer is provided above the bonding surface. The wiring layer is provided above the second circuit layer. The wiring layer includes a pad electrically connected to the CMOS circuit via the second circuit layer. The second circuit layer includes a layer stack and a plurality of first pillars. The layer stack includes, in the first area, a plurality of first insulating layers and a plurality of first conductive layers alternately stacked in a second direction crossing the first direction and includes, in the second area, the first insulating layers and the first conductive layers or a plurality of first members alternately stacked in the second direction. A material of the first members is different from both of materials of the first insulating layers and the first conductive layers. The first pillars, in the first area, penetrates the layer stack in the second direction and are electrically connected to a source line above the layer stack. The pad has a portion overlapping with the layer stack in the second direction and does not have a portion overlapping with the source line in the second direction.

Hereinbelow, embodiments are described with reference to the drawings. Each embodiment gives examples of a device and a method for embodying the technical idea of the invention. The drawings are schematic or conceptual ones. The dimensions, ratios, etc. of drawings are not necessarily the same as the actual ones. The illustration of the configuration is omitted as appropriate. The hatching added to the plan view is not necessarily related to the material or characteristics of the component. In the present specification, components having substantially the same function and configuration are marked with the same reference signs. The numerals, characters, etc. added to reference signs are referred to by the same reference signs, and are used to distinguish between similar elements.

### <1> First Embodiment

A first embodiment relates to a memory device having a structure in which a source line in an area where an end portion of a memory cell array and a pad exposed on a surface of a memory device overlap is removed and an insulating film is embedded in the area. A memory device 1 according to the first embodiment will now be described.

### <1-1> Configuration

First, a configuration of the memory device 1 according to the first embodiment is described.

### <1-1-1> Overall Configuration of the Memory Device 1

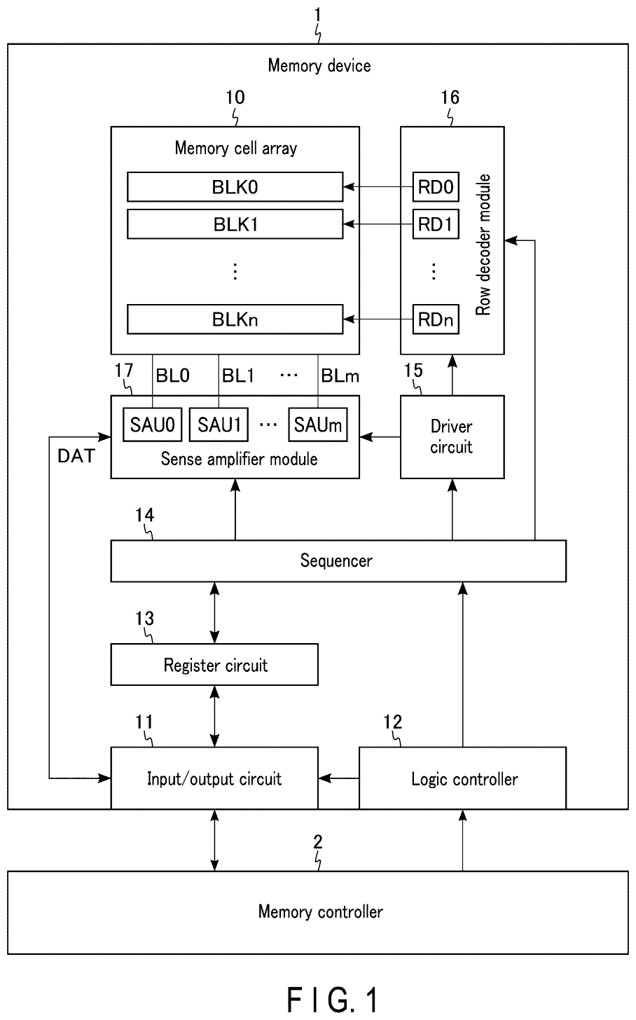

FIG. 1 is a block diagram showing an example of an overall configuration of a memory system including the memory device 1 according to the first embodiment. As shown in FIG. 1, the memory device 1 is controlled by a memory controller 2 in the outside. The memory device 1 is, for example, a NAND flash memory capable of storing data in a nonvolatile manner. The memory device 1 includes, for example, a memory cell array 10, an input/output circuit 11, a logic controller 12, a register circuit 13, a sequencer 14, a driver circuit 15, a row decoder module 16, and a sense amplifier module 17.

The memory cell array 10 includes a plurality of blocks BLK0 to BLKn (“n” is an integer of 1 or more). The block BLK is a set of a plurality of memory cells. The block BLK corresponds to, for example, a unit of data erasure. The block BLK includes a plurality of pages. The page corresponds to a unit in which reading and writing of data are executed. Although illustration is omitted, the memory cell array 10 is provided with a plurality of bit lines BL0 to BLm (“m” is an integer of 1 or more) and a plurality of word lines WL. Each memory cell is associated with, for example, one bit line BL and one word line WL.

The input/output circuit 11 is an interface circuit that takes charge of transmission and reception of input/output signals with the memory controller 2. The input/output signal includes, for example, data DAT, status information, address information, a command, etc.

The input/output circuit 11 can input and output data DAT between the sense amplifier module 17 and the memory controller 2. The input/output circuit 11 can output, to the memory controller 2, status information transferred from the register circuit 13. The input/output circuit 11 can output, to the register circuit 13, each of address information and a command transferred from the memory controller 2.

The logic controller 12 controls each of the input/output circuit 11 and the sequencer 14 based on a control signal inputted from the memory controller 2. For example, the logic controller 12 controls the sequencer 14 to enable the memory device 1. The logic controller 12 notifies the input/output circuit 11 that the input/output signal received by the input/output circuit 11 is a command, address information, or the like. The logic controller 12 orders the input/output circuit 11 to input or output an input/output signal.

The register circuit 13 temporarily stores status information, address information, and a command. The status information is updated based on the control of the sequencer 14, and is transferred to the input/output circuit 11. The address information includes a block address, a page address, a column address, and the like. The command includes orders regarding various operations of the memory device 1.

The sequencer 14 controls the entire operation of the memory device 1. The sequencer 14 executes a read operation, a write operation, an erase operation, or the like based on a command and address information stored in the register circuit 13.

The driver circuit 15 generates voltage used in a read operation, a write operation, an erase operation, or the like. Then, the driver circuit 15 supplies the generated voltage to the row decoder module 16, the sense amplifier module 17, or the like.

The row decoder module 16 is a circuit used to select a block BLK to be operated and transfer voltage to a wiring line such as a word line WL. The row decoder module 16 includes a plurality of row decoders RD0 to RDn. The row decoders RD0 to RDn are associated with the blocks BLK0 to BLKn, respectively, and are used to select the block BLK. Each row decoder RD transfers voltage generated by the driver circuit 15 to various wiring lines provided in the memory cell array 10.

The sense amplifier module 17 is a circuit used to transfer voltage to each bit line BL and read data. The sense amplifier module 17 includes a plurality of sense amplifier units SAU0 to SAUm. The sense amplifier units SAU0 to SAUm are associated with the bit lines BL0 to BLm, respectively. Each sense amplifier unit SAU includes a sense amplifier capable of determining data based on the voltage of the associated bit line BL, a latch circuit that temporarily holds data, etc.

A combination of the memory device 1 and the memory controller 2 may constitute one semiconductor device. Examples of such a semiconductor device include a memory card such as an SD™ card, an SSD (solid-state drive), and the like.

### <1-1-2> Circuit Configuration of the Memory Cell Array 10

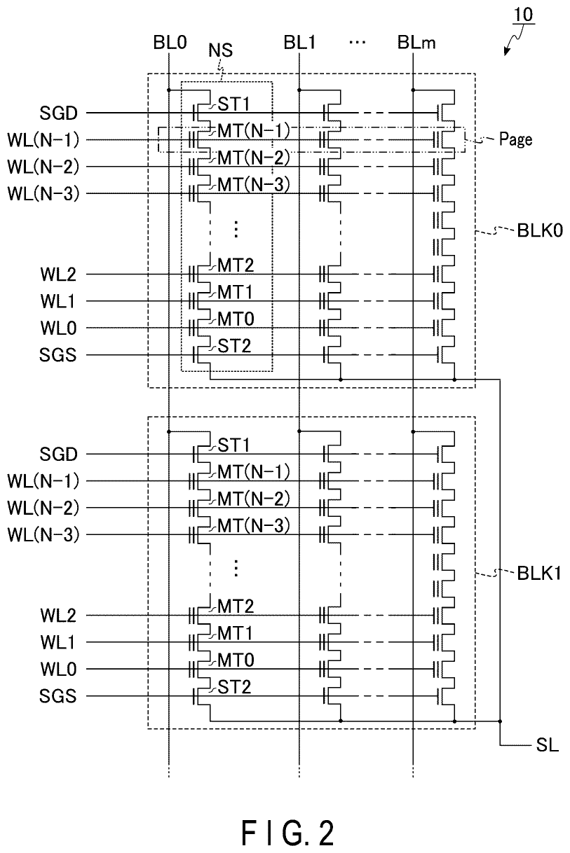

FIG. 2 is a circuit diagram showing an example of a circuit configuration of the memory cell array 10 included in the memory device 1 according to the first embodiment. FIG. 2 shows two blocks BLK0 and BLK1 among the blocks BLK included in the memory cell array 10. As shown in FIG. 2, in the memory cell array 10, select gate lines SGD and SGS and word lines WL0 to WL(N−1) (N is an integer of 2 or more) are provided for each block BLK. Bit lines BL0 to BLm and a source line SL are shared by, for example, a plurality of blocks BLK.

Each block BLK includes a plurality of NAND strings NS. The NAND strings NS are individually associated with the bit lines BL0 to BLm. In other words, each bit line BL is shared by NAND strings NS to which the same column address is allocated among a plurality of blocks BLK. Each NAND string NS is connected between the associated bit line BL and the source line SL. Each NAND string NS includes, for example, N memory cell transistors MT0 to MT(N−1) and select transistors ST1 and ST2. Each memory cell transistor MT is a memory cell including a control gate and a charge storage layer, and holds (stores) data in a nonvolatile manner. Each of the select transistors ST1 and ST2 is used to select the block BLK.

In each NAND string NS, the select transistor ST1, the memory cell transistors MT(N−1) to MT0, and the select transistor ST2 are connected in series in this order. Specifically, the drain end and the source end of the select transistor ST1 are connected to the associated bit line BL and the drain end of the memory cell transistor MT(N−1), respectively. The drain end and the source end of the select transistor ST2 are connected to the source end of the memory cell transistor MT0 and the source line SL, respectively. The memory cell transistors MT0 to MT(N−1) are connected in series between the select transistors ST1 and ST2.

Each select gate line SGD is connected to the gate end of each of the select transistors ST1 included in the associated block BLK. The select gate line SGS is connected to the gate end of each of the select transistors ST2 included in the associated block BLK. The word lines WL0 to WL(N−1) are connected to the control gate ends of the memory cell transistors MT0 to MT(N−1) included in the associated block BLK, respectively. The “page” corresponds to a set of memory cell transistors MT connected to a common word line WL in the same block BLK. The set of memory cell transistors MT connected to a common word line WL in the same block BLK can have a storage capacity of two-page data or more according to the number of bits stored in the memory cell transistors MT.

The circuit configuration of the memory cell array 10 may be another circuit configuration. For example, a plurality of independently controllable select gate lines SGD may be provided in each block BLK. In this case, each block BLK is configured such that selection can be performed in units of a plurality of units individually associated with the select gate lines SGD.

In the following, for the memory device 1 according to the first embodiment, a case where each NAND string NS includes eight memory cell transistors MT0 to MT7 connected to word lines WL0 to WL7, respectively, (that is, a case where N=8) is described as an example.

### <1-1-3> Structure of the Memory Device 1

A structure of the memory device 1 according to the first embodiment will now be described.

In the drawings referred to below, a three-dimensional orthogonal coordinate system is used. The X direction corresponds to the extending direction of the word line WL. The Y direction corresponds to the extending direction of the bit line BL. The Z direction corresponds to the vertical direction with respect to a surface of a semiconductor substrate taken as a reference. The “up and down” is defined based on a direction along the Z direction. The positive direction (upward) corresponds to a direction away from a semiconductor substrate taken as a reference. The XY plane (cross section) corresponds to a plane (cross section) parallel to each of the X direction and the Y direction. The YZ cross section corresponds to a cross section parallel to each of the Y direction and the Z direction. The XZ cross section corresponds to a cross section parallel to each of the X direction and the Z direction.

### (1: External Appearance of the Memory Device 1)

First, an external appearance of the memory device 1 according to the first embodiment is described. The memory device 1 according to the first embodiment is formed by a method in which two semiconductor circuit substrates each with a semiconductor circuit formed thereon are bonded together and the bonded semiconductor circuit substrates are separated on a chip basis. That is, the memory device 1 according to the first embodiment has a bonding surface formed by bonding semiconductor substrates W1 and W2. Each of the semiconductor substrates W1 and W2 is a silicon substrate. In the following, a case where the semiconductor substrate W2 is removed in the manufacturing process of the memory device 1 is described. Depending on the structure of the memory cell array 10, part of the semiconductor substrate W2 may remain after the semiconductor substrates W1 and W2 are bonded together.

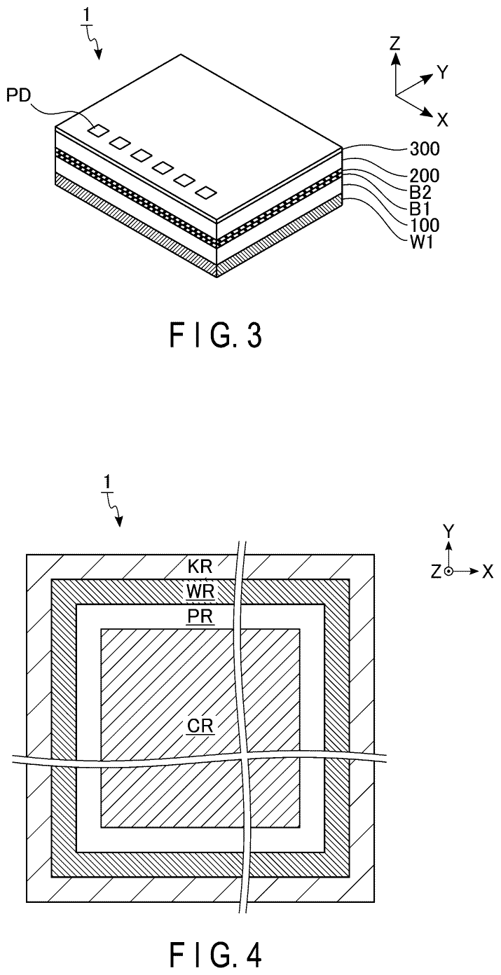

FIG. 3 is a perspective view showing an example of an external appearance of the memory device 1 according to the first embodiment. As shown in FIG. 3, the memory device 1 includes, for example, a semiconductor substrate W1, a CMOS layer 100, a bonding layer B1, a bonding layer B2, a memory layer 200, and a wiring layer 300.

The CMOS layer 100 is placed on the semiconductor substrate W1. The CMOS layer 100 includes a CMOS circuit (control circuit) formed using the semiconductor substrate W1. The semiconductor substrate W1 has an impurity diffusion region, etc. according to the design of the CMOS circuit. The CMOS layer 100 includes, for example, the input/output circuit 11, the logic controller 12, the register circuit 13, the sequencer 14, the driver circuit 15, the row decoder module 16, and the sense amplifier module 17. The CMOS layer 100 may be referred to as a circuit layer.

The bonding layer B1 is placed on the CMOS layer 100. The bonding layer B1 is formed using the semiconductor substrate W1. The bonding layer B1 includes a plurality of bonding pads electrically connected to the CMOS circuit provided in the CMOS layer 100 and forming parts of the semiconductor circuit.

The bonding layer B2 is placed on the bonding layer B1. The bonding layer B2 is formed using a semiconductor substrate W2 (not illustrated). The bonding layer B2 includes a plurality of bonding pads electrically connected to the memory cell array 10 provided in the memory layer 200 and forming parts of the semiconductor circuit. The bonding pads included in the bonding layer B2 are individually connected to the bonding pads included in the bonding layer B1. A portion between the bonding layers B1 and B2 corresponds to a boundary portion between a layer formed using the semiconductor substrate W1 and a layer formed using the semiconductor substrate W2, that is, a bonding surface.

The memory layer 200 is placed on the bonding layer B2. The memory layer 200 includes a memory cell array 10 formed using the semiconductor substrate W2, etc. The memory layer 200 may be referred to as a circuit layer.

The wiring layer 300 is placed on the memory layer 200. The wiring layer 300 is formed after the semiconductor substrates W1 and W2 are bonded together. The wiring layer 300 includes wiring lines connected to the semiconductor circuit provided in the memory layer 200 and a plurality of pad units PD. Each of the pad units PD includes a conductive portion (pad) exposed on the surface of the memory device 1. The pad units PD are used for connection between the memory device 1 and the memory controller 2 or the like, supply of power, etc.

### (2: Planar Layout of the Memory Device 1)

FIG. 4 is a plan view showing an example of a planar layout of the memory device 1 according to the first embodiment. As shown in FIG. 4, the memory device 1 includes, for example, a core area CR, a peripheral area PR, a wall area WR, and a kerf area KR.

The core area CR is, for example, a rectangular area provided in the vicinity of the center of the semiconductor substrate W1. In the core area CR, for example, the memory cell array 10, the register circuit 13, the sequencer 14, the driver circuit 15, the row decoder module 16, the sense amplifier module 17, etc. are arranged.

The peripheral area PR is an area in a quadrangular ring shape provided to surround the outer periphery of the core area CR.

In the peripheral area PR, for example, the input/output circuit 11, the logic controller 12, etc. are arranged. Further, in the peripheral area PR, for example, contacts, etc. for connecting wiring lines provided in the wiring layer 300 and a circuit provided in the CMOS layer 100 or the memory layer 200 are arranged.

The wall area WR is an area in a quadrangular ring shape provided to surround the outer periphery of the peripheral area PR. In the wall area WR, at least one sealing unit ES (not illustrated) provided to surround the outer periphery of the peripheral area PR is placed. Details of the sealing unit ES will be described later.

The kerf area KR is an area in a quadrangular ring shape provided to surround the outer periphery of the wall area WR. The kerf area KR is in contact with the outermost periphery of the memory device 1. In the kerf area KR, for example, an alignment mark, etc. used at the time of manufacturing the memory device 1 are arranged. The structure of the kerf area KR may be removed in a dicing step of cutting the semiconductor circuit substrate on a chip (memory device 1) basis.

### (3: Planar Layout of the Memory Cell Array 10)

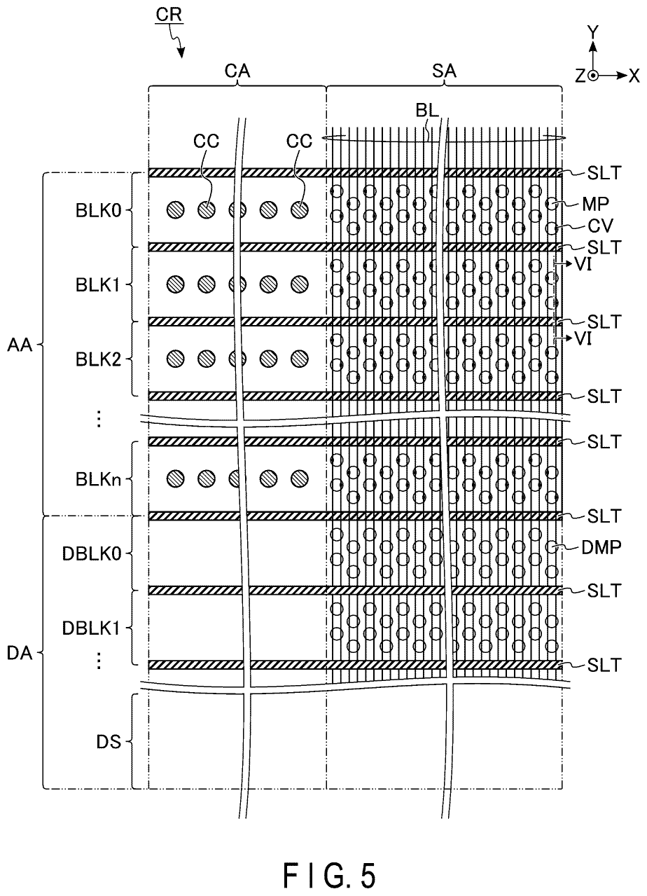

FIG. 5 is a plan view showing an example of a planar layout in the core area CR of the memory cell array 10 included in the memory device 1 according to the first embodiment. As shown in FIG. 5, the memory cell array 10 includes a plurality of slits SLT, a plurality of memory pillars MP, and pluralities of contacts CV and CC. Further, the memory cell array 10 includes, for example, a storage area SA and a contact area CA arranged in the X direction.

Each slit SLT is a plate-like member provided to extend along the X direction. Each slit SLT has a portion provided to extend along the X direction, and crosses the storage area SA and the contact area CA along the X direction. The slits SLT are arranged in the Y direction. Each slit SLT divides wiring lines adjacent via the slit SLT (for example, the word lines WL0 to WL7 and the select gate lines SGD and SGS). In each slit SLT, a conductor provided with a spacer of an insulator on its side wall may be placed to be insulated from these wiring lines, or an insulator may be embedded. In the memory cell array 10, each of the areas partitioned along the Y direction by the slits SLT corresponds to one block BLK.

The storage area SA includes a plurality of memory pillars MP. Each memory pillar MP is, for example, a pillar-like member functioning as one NAND string NS. A plurality of memory pillars MP are arranged in a lattice configuration for each block BLK. At least one bit line BL is placed to overlap with each memory pillar MP. The bit lines BL each have a portion provided to extend in the Y direction, and are arranged in the X direction. In the present example, two bit lines BL are arranged to overlap with one memory pillar MP. The memory pillar MP and the bit line BL associated with each other are electrically connected to each other via a contact CV.

The contact area CA is used for connection between stacked wiring lines (for example, the word lines WL and the select gate lines SGD and SGS) included in the memory cell array 10 and the row decoder module 16. In the contact area CA, a plurality of contacts CC are arranged for each block BLK. For each block BLK, each of the contacts CC is electrically connected to one associated wiring line of the stacked wiring lines. In each block BLK, at least one contact CC is electrically connected to the select gate line SGS, the word lines WL0 to WL7, and the select gate line SGD.

In the contact area CA, the contacts CC in each block BLK are not limited to an arrangement in a line in the X direction like that shown in FIG. 5, and may be arranged in a lattice configuration for each block BLK. In the core area CR, two contact areas CA may be arranged to sandwich the storage area SA in the X direction. Further, the contact area CA may be placed to divide the storage area SA in the X direction.

The core area CR includes an active area AA and a dummy area DA arranged in the Y direction. Each of the active area AA and the dummy area DA overlaps with each of the storage area SA and the contact area CA. A plurality of memory pillars MP used to store data are arranged in an area where the storage area SA and the active area AA overlap. A plurality of contacts CC used to control active blocks BLK are arranged in an area where the contact area CA and the active area AA overlap.

The dummy area DA is placed in an end portion in the Y direction of the core area CR. In the core area CR, two dummy areas DA can be arranged to sandwich the active area AA in the Y direction. A dummy block DBLK corresponds to an area partitioned in the Y direction by slits SLT in the dummy area DA. The dummy area DA includes at least one dummy block DBLK. In FIG. 5, two dummy blocks DBLK0 and DBLK1 arranged in the Y direction are shown. A plurality of dummy pillars DMP can be arranged in an area of the dummy block DBLK overlapping with the storage area SA. The dummy pillars DMP are a pattern for compensating for the configuration of memory pillars MP, and each have a similar structure to the memory pillar MP. The dummy pillar DMP is not connected to a contact CV, nor to a bit line BL. Thus, the dummy pillar DMP is not used to store data.

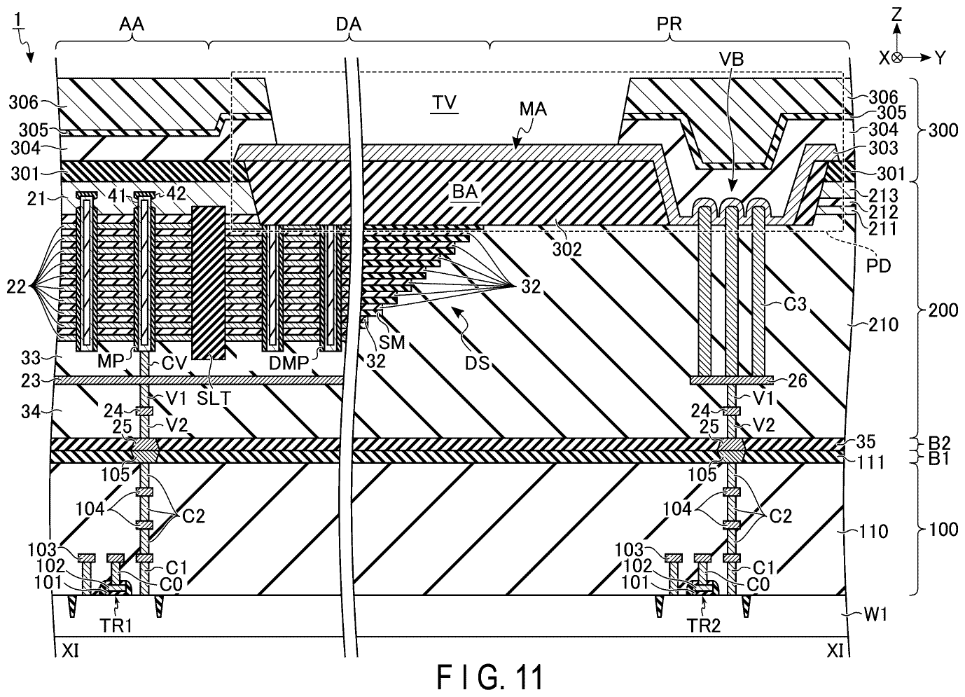

The dummy area DA further includes a dummy staircase portion DS in a portion corresponding to the outer edge of the core area CR. The dummy staircase portion DS includes end portions of stacked wiring lines provided in a staircase shape. In the dummy staircase portion DS, sacrificial members SM remain in portions corresponding to the stacked wiring lines. The sacrificial member SM is a member used in replacement processing of forming the stacked wiring lines. In the replacement processing, out of alternately stacked sacrificial members SM and insulating layers, the sacrificial members SM are replaced with a conductor; thereby, stacked wiring lines are formed. More specifically, in the replacement processing, the sacrificial members SM are removed via the slit SLT, and a conductor is embedded in the space where the sacrificial members SM have been removed. Thus, sacrificial members SM provided in portions away from the slit SLT can remain without being replaced with the conductor in the replacement processing. Thereby, end portions of the stacked sacrificial members SM are provided in a staircase shape. An example of the structure of the dummy staircase portion DS is shown in FIG. 11 described later.

### (4: Cross-Sectional Structure in the Storage Area SA of The Memory Cell Array 10)

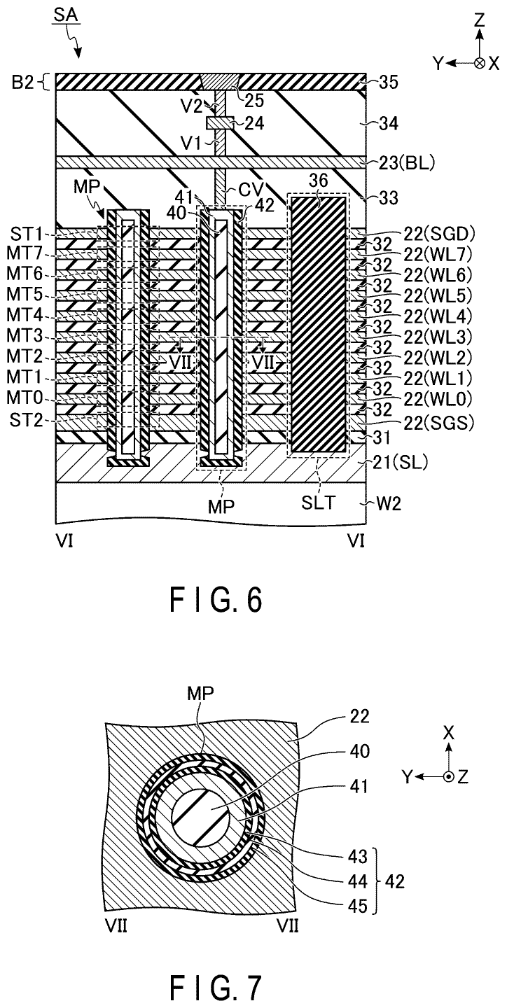

FIG. 6 is a cross-sectional view taken along line VI-VI of FIG. 5, showing an example of a cross-sectional structure in the storage area SA of the memory cell array 10 included in the memory device 1 according to the first embodiment. FIG. 6 shows an example of a structure of the memory cell array 10 formed on the semiconductor substrate W2 before being bonded to the semiconductor substrate W1 and the bonding layer B2 above the structure, and shows coordinate axes with the semiconductor substrate W2 as a reference. As shown in FIG. 6, in the storage area SA, the memory cell array 10 includes, for example, conductive layers 21 to 24, insulating layers 31 to 34, an insulating member 36, and contacts CV, V1, and V2.

A conductive layer 21 is provided on the semiconductor substrate W2. An insulating layer 31 is provided on the conductive layer 21. On the insulating layer 31, a conductive layer 22 and an insulating layer 32 are alternately provided in the Z direction. That is, a plurality of conductive layers 22 are arranged in the Z direction. Thus, a layer stack corresponding to the memory cell array 10 includes conductive layers 22 and insulating layers 32 alternately provided in the Z direction. The number of conductive layers 22 corresponds to, for example, the number of stacked wiring lines (the select gate line SGS, the word lines WL, and the select gate line SGD).

An insulating layer 33, a conductive layer 23, and an insulating layer 34 are provided in this order on the uppermost conductive layer 22. Each of the conductive layers 21 and 22 is, for example, formed in a plate shape spreading along the XY plane. The conductive layer 23 has, for example, a portion formed in a line shape extending in the Y direction. The conductive layer 21 is used as the source line SL. In the present example, the ten conductive layers 22 arranged in the Z direction are used as the select gate line SGS, the word lines WL0 to WL7, and the select gate line SGD in this order from the source line SL side. The conductive layer 23 is used as the bit line BL. The conductive layer 21 contains, for example, polysilicon (Si). The conductive layer 22 contains, for example, tungsten (W). The conductive layer 23 contains, for example, copper (Cu).

A conductive layer 24 is provided above the conductive layer 23. The conductive layer 24 is a wiring line that relays connection between the bit line BL and the sense amplifier module 17. The conductive layer 23 and the conductive layer 24 are connected to each other via a contact V1. A conductive layer 25 is provided above the conductive layer 24. The conductive layer 25 corresponds to a bonding pad. The conductive layer 24 and the conductive layer 25 are connected to each other via a contact V2. The side surfaces of the conductive layer 24 and the contacts V1 and V2 are covered with an insulating layer 34. The insulating layer 34 can include a plurality of insulating films. The side surface of the conductive layer 25 is covered with an insulating layer 35. The insulating layer 35 and the conductive layer 25 are included in the bonding layer B2. The memory cell array 10 can include a plurality of conductive layers 24. The bonding layer B2 can include a plurality of conductive layers 25. The conductive layer 25 contains, for example, copper.

The insulating member 36 has a portion formed in a plate shape spreading along the XZ plane. The insulating member 36 divides the insulating layer 31 and the alternately provided conductive layers 22 and insulating layers 32. In the present example, the insulating member 36 is embedded in the slit SLT. In the slit SLT, a conductor provided with a spacer of an insulator on its side wall may be placed to be insulated from the conductive layers 21 and 22.

Each memory pillar MP is provided to extend along the Z direction, penetrates the insulating layer 31 and the alternately provided conductive layers 22 and insulating layers 32, and is connected to the conductive layer 21. Each memory pillar MP includes, for example, a core member 40, a semiconductor layer 41, and a stacked film 42. The core member 40 is an insulator provided to extend along the Z direction. The semiconductor layer 41 covers the core member 40. Part of the side surface of the semiconductor layer 41 is in contact with the conductive layer 21. That is, the semiconductor layer 41 in the memory pillar MP and the conductive layer 21 (the source line SL) are electrically connected to each other via the side surface of the memory pillar MP. The stacked film 42 covers the side surface and the bottom surface of the semiconductor layer 41 except for a contact portion between the semiconductor layer 41 and the conductive layer 21. The semiconductor layer 41 (the memory pillar MP) and the conductive layer 23 (the bit line BL) associated with each other are connected to each other via a contact CV.

A portion where the conductive layer 22 used as the select gate line SGS and the memory pillar MP cross each other functions as a select transistor ST2. A portion where the conductive layer 22 used as the word line WL and the memory pillar MP cross each other functions as a memory cell transistor MT. A portion where the conductive layer 22 used as the select gate line SGD and the memory pillar MP cross each other functions as a select transistor ST1. In each memory pillar MP, the semiconductor layer 41 is used as channels (current paths) of the memory cell transistors MT0 to MT7 and the select transistors ST1 and ST2 included in a NAND string NS.

### (5: Cross-Sectional Structure of the Memory Pillar MP)

FIG. 7 is a cross-sectional view taken along line VII-VII of FIG. 6, showing an example of a cross-sectional structure of the memory pillar MP included in the memory device 1 according to the first embodiment. FIG. 7 shows a cross section including the memory pillar MP and the conductive layer 22 and parallel to the surface of the semiconductor substrate W2. As shown in FIG. 7, the stacked film 42 includes, for example, a tunnel insulating film 43, an insulating film 44, and a block insulating film 45. The tunnel insulating film 43 surrounds the side surface of the semiconductor layer 41. The insulating film 44 surrounds the side surface of the tunnel insulating film 43. The block insulating film 45 surrounds the side surface of the insulating film 44. The conductive layer 22 surrounds the side surface of the block insulating film 45. Each of the tunnel insulating film 43 and the block insulating film 45 includes, for example, a silicon oxide film (SiO₂). The insulating film 44 is used as a charge storage layer of the memory cell transistor MT. The insulating film 44 contains, for example, silicon nitride (SiN).

### (6: Cross-Sectional Structure of the Memory Device 1)

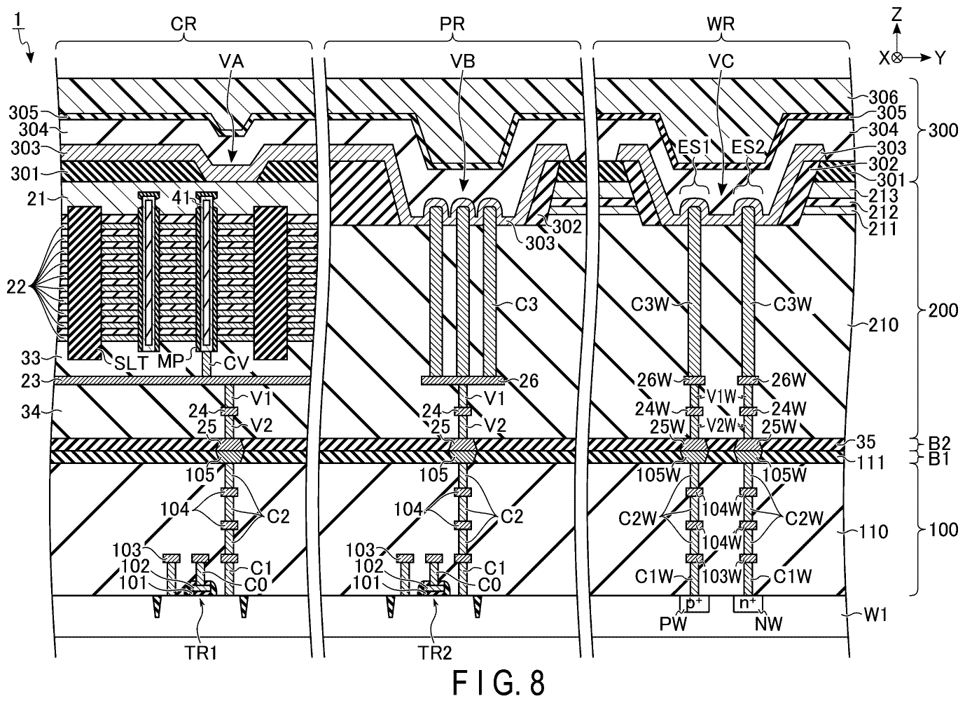

FIG. 8 is a cross-sectional view showing an example of a cross-sectional structure of the memory device 1 according to the first embodiment. FIG. 8 shows parts of the core area CR, the peripheral area PR, and the wall area WR after the semiconductor substrate W1 and the semiconductor substrate W2 are bonded together, and shows coordinate axes with the semiconductor substrate W1 as a reference. In the present example, the semiconductor substrate W2 is removed after the processing of bonding the semiconductor substrates W1 and W2. In the core area CR, the memory layer 200 and the bonding layer B2 have a structure in which the structure related to the memory cell array 10 shown in FIG. 6 is vertically inverted and placed. As shown in FIG. 8, the CMOS layer 100 includes an insulating layer 110. The bonding layer B1 includes an insulating layer 111. The memory layer 200 includes an insulating layer 210, a conductive layer 211, a sacrificial member 212, and a conductive layer 213. The wiring layer 300 includes an insulating layer 301, an insulating member 302, a conductive layer 303, an insulating layer 304, an insulating layer 305, and an insulating layer 306.

The insulating layer 110 is provided on the semiconductor substrate W1. The insulating layer 110 covers at least parts of wiring lines, contacts, elements, etc. provided in the CMOS layer 100. The insulating layer 110 may include a plurality of kinds of insulating films. The insulating layer 111 is provided on the insulating layer 110. The insulating layer 111 covers the side surfaces of bonding pads provided in the bonding layer B1. An insulating layer 35 of the bonding layer B2 is provided on the insulating layer 111.

The insulating layer 210 is provided on the insulating layer 35. The insulating layer 210 covers at least parts of wiring lines, contacts, elements, etc. provided in the memory layer 200. The insulating layer 210 can include a plurality of kinds of insulating films, and can include insulating layers 33 and 34. The conductive layer 211, the sacrificial member 212, and the conductive layer 213 are sequentially stacked on the insulating layer 210. A set of the conductive layer 211, the sacrificial member 212, and the conductive layer 213 is provided at the height of the conductive layer 21. Specifically, the height of the lower surface of the conductive layer 211 is aligned with the height of the lower surface of the conductive layer 21 (the source line SL). The height of the upper surface of the conductive layer 213 is aligned with the height of the upper surface of the conductive layer 21 (the source line SL). The conductive layer 21 in the core area CR corresponds to a structure in which, after the conductive layer 211, the sacrificial member 212, and the conductive layer 213 are stacked, the sacrificial member 212 is replaced with a conductor. That is, the height of the sacrificial member 212 is the same as the height at which the conductive layer 21 and the semiconductor layer 41 in each memory pillar MP are connected to each other. Each of the conductive layers 211 and 213 contains, for example, polysilicon (Si). The sacrificial member 212 contains, for example, silicon nitride (SiN).

The insulating layer 301 is provided on the conductive layer 213 and the conductive layer 21. In each of part of the peripheral area PR and part of the wall area WR, the insulating member 302 is provided to penetrate the insulating layer 301, the conductive layer 213, the sacrificial member 212, and the conductive layer 211. The upper surface of the insulating member 302 may be aligned with the upper surface of the insulating layer 301, or a level difference may be formed between the insulating member 302 and the insulating layer 301. The lower surface of the insulating member 302 may be aligned with the lower surface of the conductive layer 211, or may be located at a height between the lower surface of the conductive layer 211 and a conductive layer 26 described later.

The conductive layer 303 is provided on the insulating layer 301. In the peripheral area PR and the wall area WR, the conductive layer 303 can have a portion provided on the insulating member 302. The conductive layer 303 is divided (insulated) at least between the peripheral area PR and the wall area WR. The conductive layer 303 can have a portion continuously provided between the core area CR and the peripheral area PR.

The wiring layer 300 includes a via VA in the core area CR, a via VB in the peripheral area PR, and a via VC in the wall area WR. The via VA penetrates the insulating layer 301. The conductive layer 303 in the core area CR is provided along the via VA, and can have a portion connected to the conductive layer 21 via the via VA. The via VB penetrates the insulating member 302. The conductive layer 303 in the peripheral area PR is provided along the via VB, and can have a portion connected to a contact C3 described later via the via VB. A portion of the conductive layer 303 provided in the via VB and the conductive layers 211 and 213 are insulated from each other by the insulating member 302. The via VC penetrates the insulating member 302. The conductive layer 303 in the wall area WR is provided along the via VC, and can have a portion connected to sealing units ES1 and ES2 described later via the via VC. A portion of the conductive layer 303 provided in the via VC and the conductive layers 211 and 213 are insulated from each other by the insulating member 302.

The insulating layer 304, the insulating layer 305, and the insulating layer 306 are provided in this order on the insulating layer 301 or the conductive layer 303. Each of the insulating layer 304, the insulating layer 305, and the insulating layer 306 has a portion provided along each of the vias VA, VB, and VC. Each of the insulating layer 301, the insulating member 302, and the insulating layer 304 includes, for example, a silicon oxide film (SiO₂). The insulating layer 305 contains, for example, silicon nitride (SiN). The insulating layer 306 contains, for example, a polyimide.

In the core area CR, the CMOS layer 100 includes a gate insulating film 101, a gate electrode 102, conductive layers 103 and 104, and contacts C0 to C2, and the bonding layer B1 includes a conductive layer 105. The gate insulating film 101 is provided on the semiconductor substrate W1. The gate electrode 102 of the core area CR is provided on the gate insulating film 101, and is used as a gate electrode of a transistor TR1. The transistor TR1 is included in, for example, the sense amplifier module 17. The conductive layers 103 are wiring lines above the gate electrode 102. The contact C0 connects the gate electrode 102 and a conductive layer 103. The contact C1 connects an impurity diffusion region of the transistor TR1 provided on the semiconductor substrate W1 and a conductive layer 103. The conductive layers 104 are wiring lines provided at heights between the conductive layer 103 and the bonding layer B1. The contacts C2 are provided at heights between the conductive layer 103 and the bonding layer B1. The at least one conductive layer 103 is connected to the conductive layer 105 via at least one contact C2 and at least one conductive layer 104. The conductive layer 105 corresponds to a bonding pad placed in the bonding layer B1. The conductive layer 105 is in contact with the conductive layer 25 placed to face the conductive layer 105 in the bonding layer B2. Thereby, the semiconductor layer 41 in the core area CR is electrically connected to the transistor TR1 via the conductive layers 23 to 25 and 103 to 105, and the contacts CV, V1, V2, C1, and C2.

In the peripheral area PR, like in the core area CR, the CMOS layer 100 includes a gate insulating film 101, a gate electrode 102, conductive layers 103 and 104, and contacts C0 to C2, and the bonding layer B1 includes a conductive layer 105. The gate electrode 102 of the peripheral area PR is used as a gate electrode of a transistor TR2. The transistor TR2 may be, for example, connected to a power supply line, or included in the input/output circuit 11. In the peripheral area PR, the bonding layer B2 includes a conductive layer 25, and the memory layer 200 includes conductive layers 24 and 26 and contacts V1, V2, and C3. The conductive layer 26 is a wiring line provided in the same layer as the conductive layer 23. At least one contact C3 is provided on the conductive layer 26. An upper portion of each contact C3 reaches at least the height of the conductive layer 211. An upper portion of each contact C3 is covered with the conductive layer 303, and is electrically connected to the conductive layer 303. Thereby, the conductive layer 303 in the peripheral area PR is electrically connected to the transistor TR2 via at least one contact C3, the conductive layers 24 to 26 and 103 to 105, and the contacts V1, V2, C1, and C2.

In the wall area WR, the memory device 1 includes contacts C1W, C2W, C3W, V1W, and V2W and conductive layers 103W, 104W, 105W, 24W, 25W, and 26W for each of sealing units ES1 and ES2. The contacts C1W, C2W, C3W, V1W, and V2W are provided in the same layers as the contacts C1, C2, C3, V1, and V2, respectively. The conductive layers 103W, 104W, 105W, 24W, 25W, and 26W are provided in the same layers as the conductive layers 103, 104, 105, 24, 25, and 26, respectively. Although illustration is omitted, a set of the contacts C1W, C2W, C3W, V1W, and V2W and the conductive layers 103W, 104W, 105W, 24W, 25W, and 26W is provided in a ring shape in a planar view. That is, in the wall area WR, each of the sealing units ES1 and ES2 is provided in a quadrangular ring shape to surround the outer periphery of the core area CR, and surrounds the peripheral area PR. The sealing unit ES2 is placed on the outside of the sealing unit ES1.

In the wall area WR, the semiconductor substrate W1 includes a P-type well region PW and an N-type well region NW. The P-type well region PW is a P-type impurity diffusion region (p⁺) provided in the vicinity of the upper surface of the semiconductor substrate W1. The N-type well region NW is an N-type impurity diffusion region (n⁺) provided in the vicinity of the upper surface of the semiconductor substrate W1. The P-type well region PW and the N-type well region NW are associated with the sealing units ES1 and ES2, respectively. The conductive layer 303 in the wall area WR is connected to the P-type well region PW via the contacts C1W, C2W, C3W, V1W, and V2W and the conductive layers 103W, 104W, 105W, 24W, 25W, and 26W corresponding to the sealing unit ES1. Further, the conductive layer 303 in the wall area WR is connected to the N-type well region NW via the contacts CIW, C2W, C3W, V1W, and V2W and the conductive layers 103W, 104W, 105W, 24W, 25W, and 26W corresponding to the sealing unit ES2.

The sealing units ES1 and ES2 described hereinabove are structures capable of releasing positive charges and negative charges generated inside and outside the wall area WR to the semiconductor substrate W1. Further, each of the sealing units ES1 and ES2 can suppress permeation of moisture or the like into the core area CR from the outside of the wall area WR. Each of the sealing units ES1 and ES2 can suppress stress generated in an interlayer insulating film (for example, tetraethoxysilane (TEOS)) of the memory device 1. Further, each of the sealing units ES1 and ES2 can be used also as a crack stopper.

### (7: Planar Layout of the Wiring Layer 300)

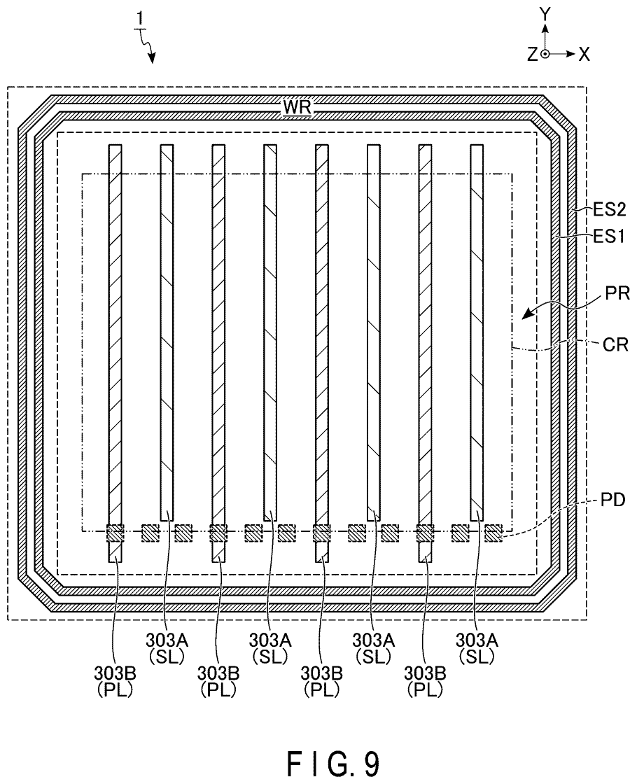

FIG. 9 is a plan view showing an example of a planar layout of the wiring layer 300 in the memory device 1 according to the first embodiment. FIG. 9 extracts and shows the core area CR, the peripheral area PR, the wall area WR, and some wiring lines and some pad units PD. As shown in FIG. 9, in the wall area WR, the sealing unit ES1 is provided to surround the outer peripheries of the core area CR and the peripheral area PR. The sealing unit ES2 is provided to surround the outer periphery of the sealing unit ES1.

A plurality of conductive layers 303 are arranged on the inside of the wall area WR. Each of the conductive layers 303 has a portion provided to extend in the Y direction. The conductive layers 303 are arranged in the X direction. The conductive layers 303 include, for example, conductive layers 303A used as parts of the source line SL and conductive layers 303B used as parts of a power supply line PL. The conductive layers 303A and 303B are, for example, alternately arranged. The conductive layer 303A corresponds to, for example, the conductive layer 303 having a portion connected to the conductive layer 21 via the via VA in the core area CR shown in FIG. 8. On the other hand, the conductive layer 303B does not have a portion connected to the conductive layer 21 via the via VA.

A plurality of pad units PD are arranged on the inside of the wall area WR. One pad unit PD is connected to each conductive layer 303B. A power supply voltage, a ground voltage, etc. are applied to the pad unit PD connected to the conductive layer 303B. On the other hand, the pad unit PD that does not overlap with the conductive layer 303A or 303B is connected to, for example, an interface circuit such as the input/output circuit 11 or the logic controller 12. At least the pad unit PD that does not overlap with the conductive layer 303A or 303B is placed to overlap with each of the core area CR and the peripheral area PR.

### (8: Planar Layout of the Pad Unit PD)

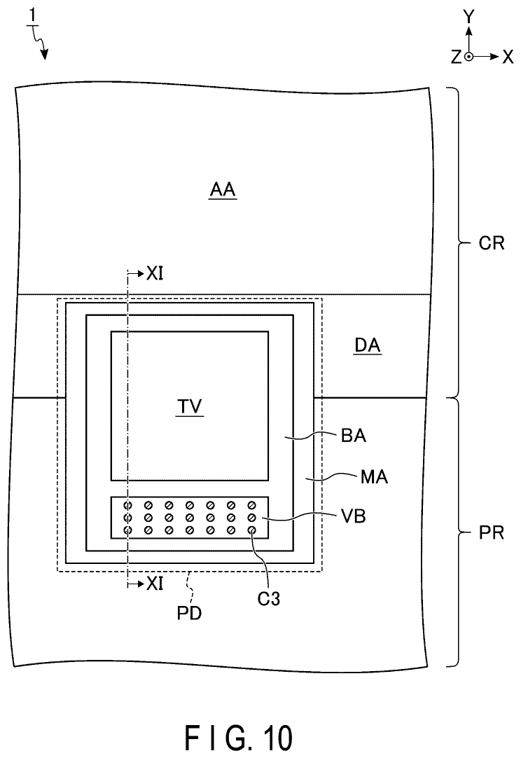

FIG. 10 is a plan view showing an example of a planar layout of the vicinity of the pad unit PD in the memory device 1 according to the first embodiment. FIG. 10 shows a pad unit PD used for connection to the input/output circuit 11, the logic controller 12, or the like in the memory device 1, and part of each of the core area CR and the peripheral area PR.

As shown in FIG. 10, the pad unit PD overlaps with each of the core area CR and the peripheral area PR. The pad unit PD has a portion overlapping with the dummy area DA of the core area CR, and does not have a portion overlapping with the active area AA. The pad unit PD includes a conductive portion MA, an insulating portion BA, a via TV, and a via VB.

The conductive portion MA includes, for example, a conductive layer 303. The conductive portion MA is, for example, provided in a rectangular shape in a planar view. The outer edge of the conductive portion MA corresponds to the outer edge of the pad unit PA. The insulating portion BA includes, for example, an insulating member 302. The insulating portion BA is, for example, provided in a rectangular shape in a planar view, and overlaps with the conductive portion MA. The outer edge of the insulating portion BA is located on the inside of the outer edge of the conductive portion MA.

Each of the vias TV and VB is, for example, provided in a rectangular shape in a planar view, and overlaps with the conductive portion MA. The vias TV and VB are arranged in the Y direction. The outer edge of each of the vias TV and VB is located on the inside of the outer edge of the insulating portion BA. The via TV is included in each of the dummy area DA and the peripheral area PR. Thus, a boundary portion between the dummy area DA and the peripheral area PR overlaps with the via TV in a planar view. Part of the conductive portion MA is exposed through the via TV. The part of the conductive portion MA exposed through the via TV corresponds to a pad used for connection between the memory device 1 and the memory controller 2. The via VB is included in the peripheral area PR, and is provided to penetrate part of the insulating portion BA. The conductive portion MA is, via the via VB, electrically connected to a plurality of contacts C3 arranged to overlap with the via VB.

### (9: Cross-Sectional Structure of the Pad Unit PD)

FIG. 11 is a cross-sectional view taken along line XI-XI of FIG. 10, showing an example of a cross-sectional structure of the vicinity of the pad unit PD in the memory device 1 according to the first embodiment. As shown in FIG. 11, in the memory device 1, the layer stack corresponding to the memory cell array 10 includes, in the dummy area DA, an insulating layer 32 and a conductive layer 22 alternately stacked in the Z direction, or an insulating layer 32 and a sacrificial member SM alternately stacked in the Z direction. The sacrificial member SM is different in material from each of the insulating layer 32 and the conductive layer 22. The dummy staircase portion DS includes, for example, an insulating layer 32 and a sacrificial member SM alternately stacked in the Z direction. That is, a plurality of sacrificial members SM are arranged in the Z direction. In other words, the layer stack corresponding to the memory cell array 10 has, in the dummy area DA, a layer stack portion in which insulating layers 32 and sacrificial members SM are alternately stacked in the Z direction. In the layer stack portion, end portions of the stacked sacrificial members SM are provided in a staircase shape. A plurality of dummy pillars DMP penetrate the layer stack corresponding to the memory cell array 10 in the dummy area DA in the Z direction.

The via TV penetrates the insulating layers 304, 305 and 306. At the bottom of the via TV, part of the conductive layer 303 corresponding to the conductive portion MA is exposed. The insulating member 302 corresponding to the insulating portion BA is provided in an area located at the same height as the source line SL and overlapping with the via TV in the Z direction. Thus, the conductive layers 21, 211, and 213 are not provided in the area overlapping with the via TV in the Z direction. In other words, the portion of the conductive layer 303 corresponding to the conductive portion MA where the surface is exposed through the via TV does not have a portion overlapping with the conductive layer 21, 211, or 213 in the Z direction. In the memory device 1 according to the first embodiment, at least the source line SL between the dummy staircase portion DS and the conductive layer 303 is removed.

The conductive layer 303 corresponding to the conductive portion MA has a portion provided along the via VB, and is connected to a plurality of contacts C3 via the via VB. Then, the conductive layer 303 corresponding to the conductive portion MA is electrically connected to the transistor TR2 on the semiconductor substrate W1 via the contacts C3. In other words, the pad corresponding to the conductive portion MA is, via the memory layer 200, electrically connected to an interface circuit (for example, the input/output circuit 11 or the logic controller 12) included in the CMOS circuit provided in the CMOS layer 100.

In a case where a level difference is formed between the insulating layer 301 and the insulating member 302, the conductive layer 303 can have a portion provided along the level difference formed between the insulating layer 301 and the insulating member 302. The via TV has at least a portion facing the dummy staircase portion DS in the Z direction, and can have a portion facing the dummy pillar DMP in the Z direction. The insulating portion BA may be provided such that part of the dummy pillar DMP is removed, or may be provided such that part of the dummy staircase portion DS is removed.

In the memory device 1 described hereinabove, in the peripheral area PR, the memory layer 200 includes a first sublayer (for example, the conductive layer 211) provided in the same layer as the source line SL and containing, as a main component, the same material as at least part of the source line SL, and a second sublayer (for example, the conductive layer 213) provided above the first sublayer via a member (for example, the sacrificial member 212). The via TV does not have a portion overlapping with the first sublayer or the second sublayer in the Z direction.

The conductive layer 303 is provided above the source line SL in the Z direction, includes a portion corresponding to the pad (the via TV), and is electrically connected to the CMOS circuit on the semiconductor substrate W1. The conductive layer 303 has a portion overlapping with the dummy pillar DMP in the Z direction, and this portion of the conductive layer 303 faces the dummy pillar DMP in the Z direction via an insulating member 302 provided at the same height as the source line SL, without interposing the source line SL. The pad (the via TV) has a portion overlapping with the dummy pillar DMP in the Z direction, and does not have a portion overlapping with the source line SL in the Z direction. The insulating layer 304 is provided to cover an upper portion of the conductive layer 303. In the insulating layer 304, a via TV is provided such that the surface of the conductive layer 303 in a portion corresponding to the pad is exposed. The memory layer 200 further includes an insulating layer 210 provided around the layer stack corresponding to the memory cell array 10 in a planar view, and at least one contact C3 that is a portion provided at the same height as the layer stack, extending in the Z direction in the insulating layer 210, and electrically connected to the CMOS circuit. The conductive layer 303 further has a portion electrically connected to the at least one contact C3.

### <1-2> Manufacturing Method

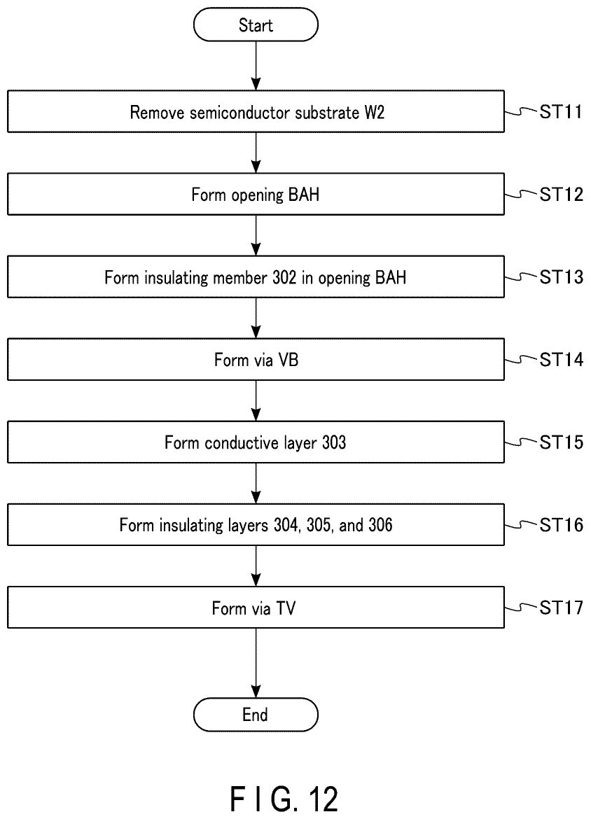

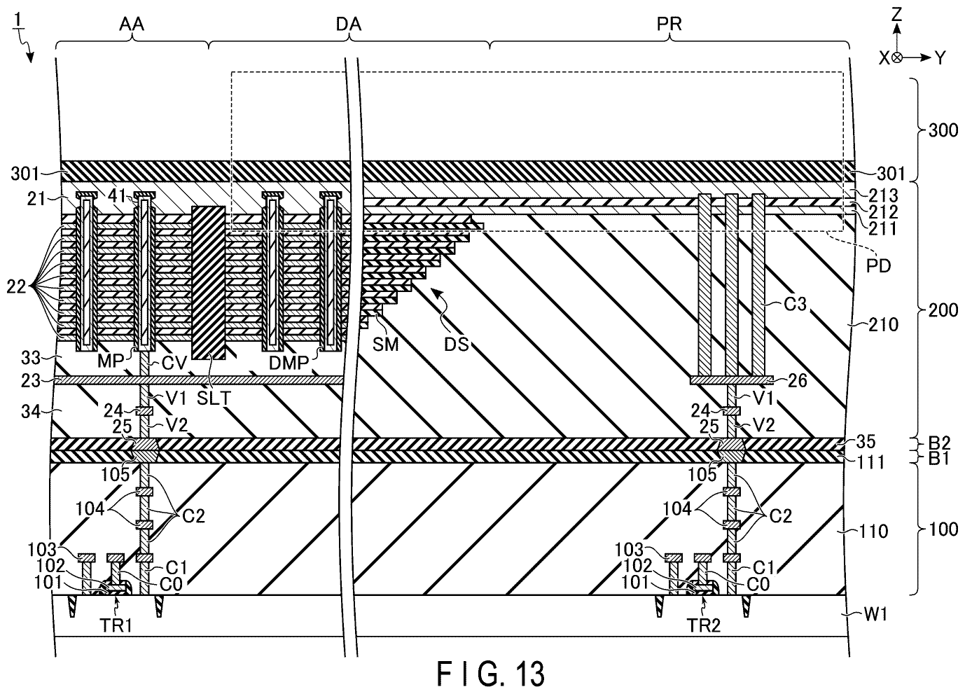

Next, as a method of manufacturing the memory device 1 according to the first embodiment, a method of forming the pad unit PD after bonding the semiconductor substrate W1 and the semiconductor substrate W2 is described with reference to FIG. 12 as appropriate. FIG. 12 is a flowchart showing an example of a method of manufacturing the memory device 1 according to the first embodiment. Each of FIGS. 13 to 17 is a cross-sectional view showing an example of a cross-sectional structure in the manufacturing process of the memory device 1 according to the first embodiment, and shows a cross section including an area in the vicinity of the pad unit PD.

First, the semiconductor substrate W2 is removed from the semiconductor substrates W1 and W2 after bonding (step ST11). For example, CMP (chemical mechanical polishing) processing is used to remove the semiconductor substrate W2. After the semiconductor substrate W2 is removed, an insulating layer 301 is formed as shown in FIG. 13. The insulating layer 301 may be formed in advance between the semiconductor substrate W2 and the conductive layer 21. In this case, the surface of the insulating layer 301 is exposed by the processing of step ST11.

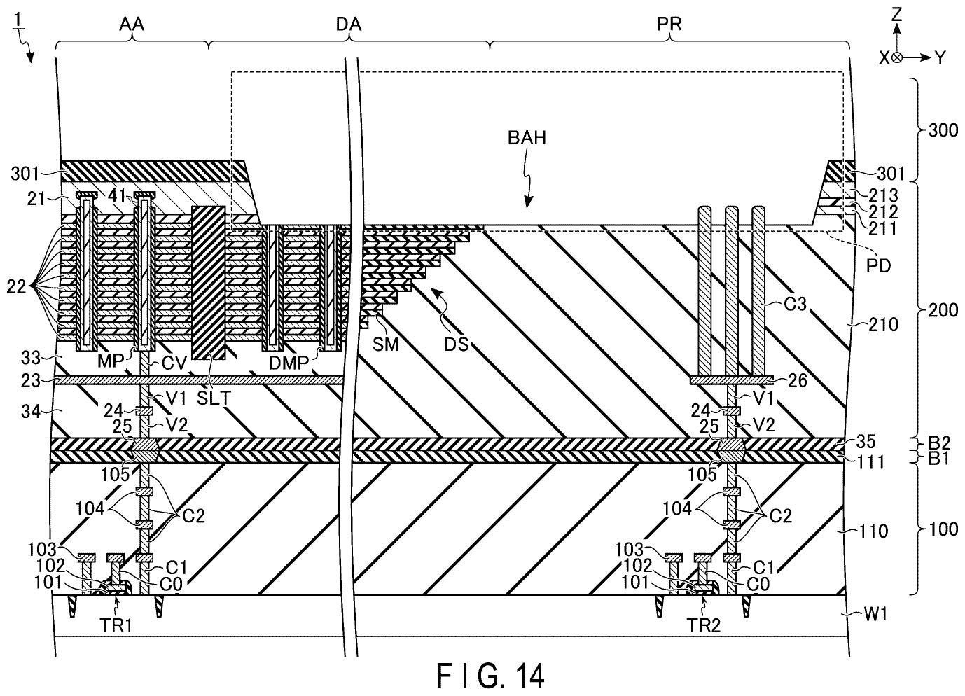

Next, as shown in FIG. 14, an opening BAH is formed (step ST12). Specifically, first, a mask in which the portion of an insulating portion BA is opened in a planar view is formed. After that, each of the insulating layer 301, the conductive layers 21, 211, and 213, and the sacrificial member 202 is removed in the opening of the mask by anisotropic etching processing, and an opening BAH is formed. In the opening BAH, upper portions of a plurality of dummy pillars DMP and upper portions of a plurality of contacts C3 are exposed. The upper portion of each of the dummy pillars DMP and the contacts C3 can remain in a protruding shape in the opening BAH.

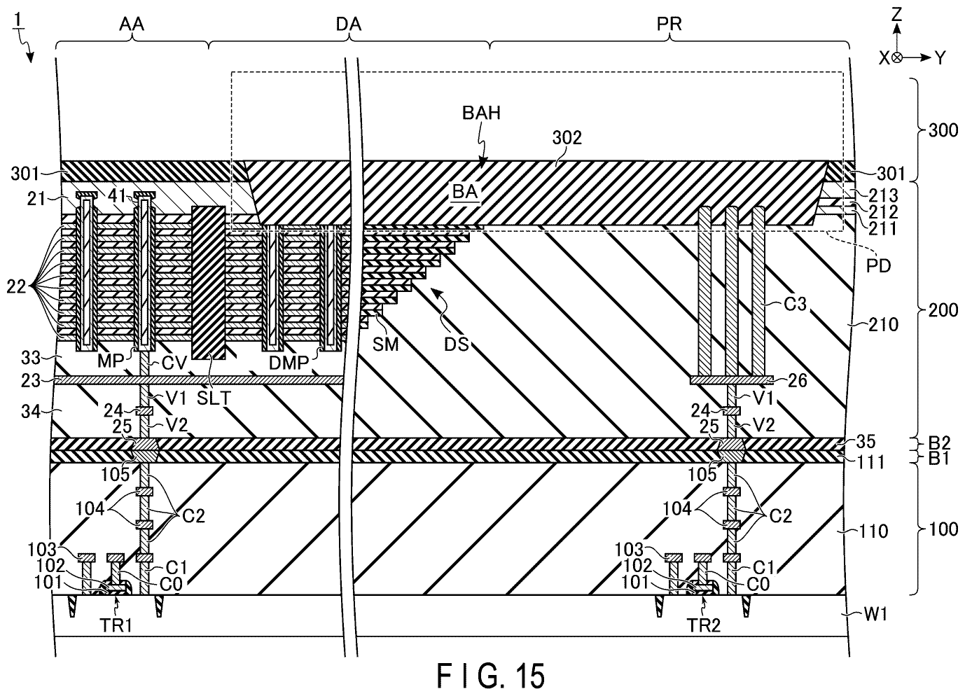

Next, as shown in FIG. 15, an insulating member 302 is formed in the opening BAH (step ST13). Specifically, first, an insulating member 302 is formed such that the opening BAH is filled. Then, for example, the insulating member 302 formed outside the opening BAH is removed by CMP processing. Thereby, the insulating member 302 remaining in the opening BAH corresponds to an insulating portion BA. In the CMP processing in step ST13, a level difference may remain between the insulating layer 301 and the insulating member 302.

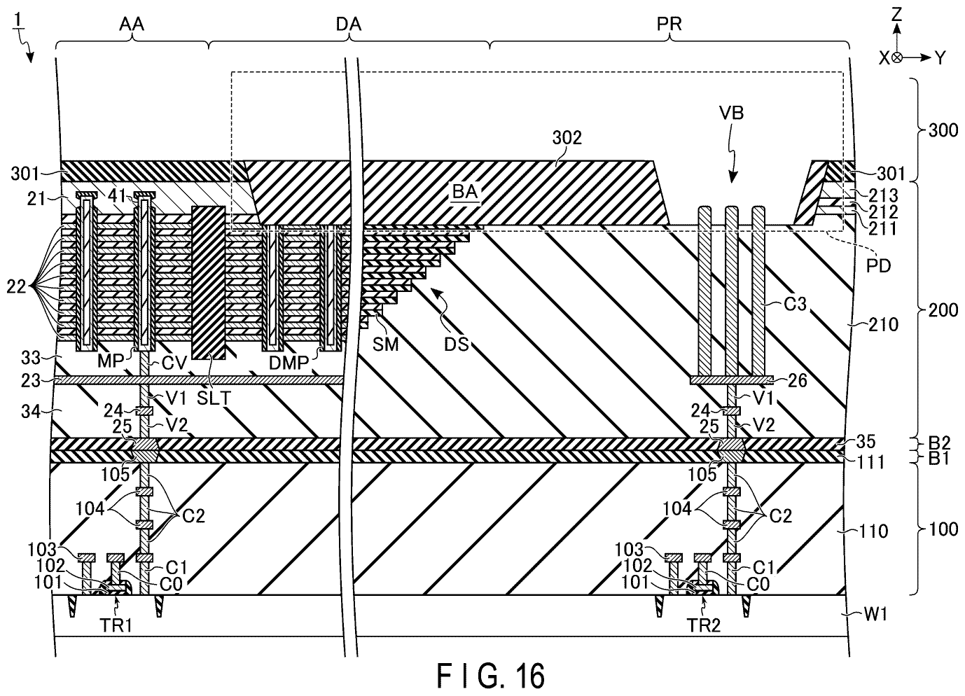

Next, as shown in FIG. 16, a via VB is formed (step ST14). Specifically, first, a mask in which the portion of a via VB is opened in a planar view is formed. After that, the insulating member 302 is removed in the opening of the mask by anisotropic etching processing, and a via VB is formed. In the via VB, upper portions of the contacts C3 are exposed.

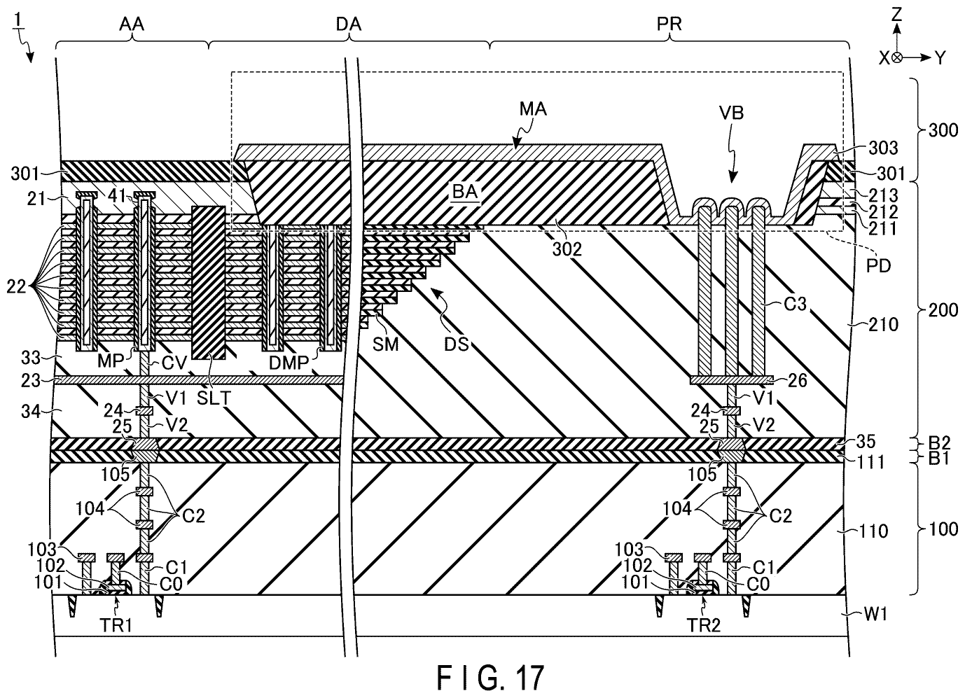

Next, as shown in FIG. 17, a conductive layer 303 is formed (step ST15). Specifically, for example, first, a conductive layer 303 is formed by CVD (chemical vapor deposition) or the like, and a mask that covers the portion of a conductive portion MA is formed. After that, anisotropic etching processing is executed to process the conductive layer 303 into the shape of the conductive portion MA.

Next, insulating layers 304, 305, and 306 are formed (step ST16), and a via TV is formed (step ST17). Thereby, a structure corresponding to the pad unit PD shown in FIG. 11 is completed.

### <1-3> Advantageous Effects of the First Embodiment

By using the memory device 1 according to the first embodiment described hereinabove, the chip size can be reduced while degradation in interface speed is suppressed. Advantageous effects of the memory device 1 according to the first embodiment will now be described using a first comparative example and a second comparative example.

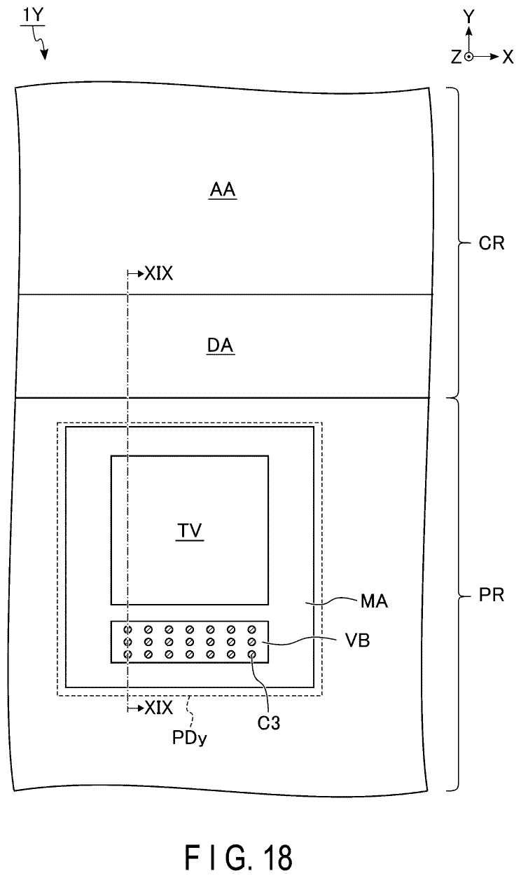

FIG. 18 is a plan view showing an example of a planar layout of the vicinity of a pad unit PDy in a memory device 1Y according to a first comparative example. As shown in FIG. 18, the pad unit PDy in the memory device 1Y according to the first comparative example is included in the peripheral area PR, and is apart from the core area CR. Unlike the pad unit PD, the pad unit PDy does not have the insulating portion BA.

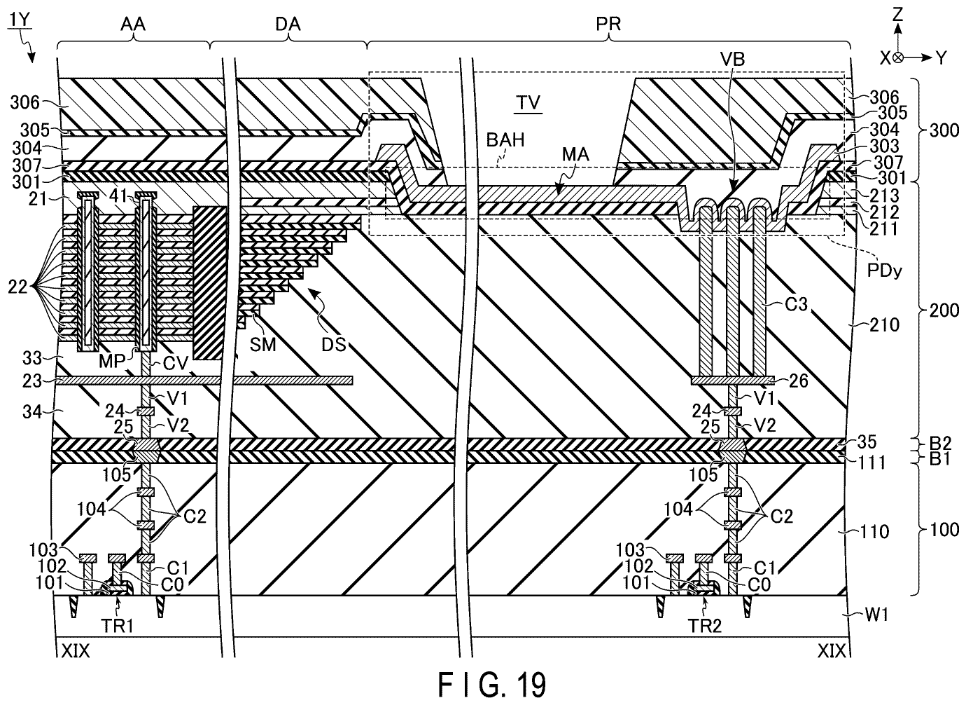

FIG. 19 is a cross-sectional view taken along line XIX-XIX of FIG. 18, showing an example of a cross-sectional structure of the vicinity of the pad unit PDy in the memory device 1Y according to the first comparative example. As shown in FIG. 19, in the memory device 1Y, the insulating member 302 is replaced with an insulating layer 307. The insulating layer 307 is provided on the insulating layer 301, and has a portion provided along the opening BAH and the via VB. The conductive layer 303 corresponding to the conductive portion MA is provided along the insulating layer 307, and is connected to the contacts C3 via the via VB. In the memory device 1Y, the structure corresponding to the source line SL is removed in a lower portion of the via TV. Thereby, parasitic capacitance between the conductive portion MA and the source line SL can be suppressed. On the other hand, the chip size of the memory device 1Y can increase according to the layout of the pad unit PDy.

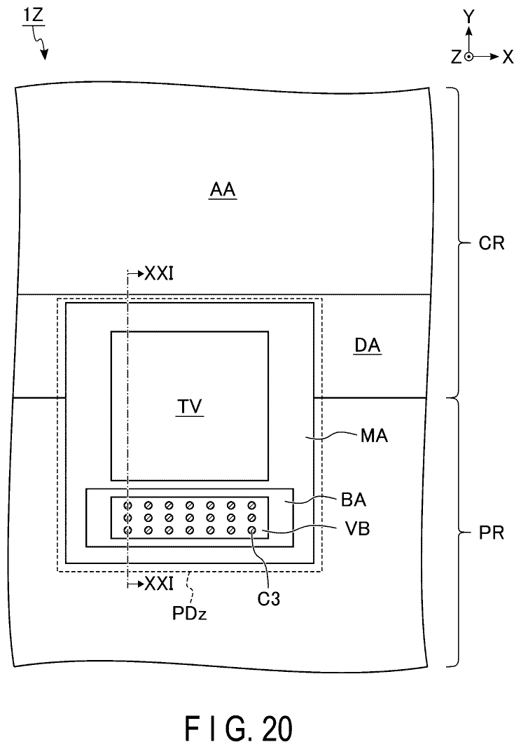

FIG. 20 is a plan view showing an example of a planar layout of the vicinity of a pad unit PDz in a memory device 1Z according to a second comparative example. As shown in FIG. 20, like in the first embodiment, the pad unit PDz in the memory device 1Z according to the second comparative example has a portion overlapping with the dummy area DA. On the other hand, the insulating portion BA in the pad unit PDz is provided not to overlap with the via TV in a planar view.

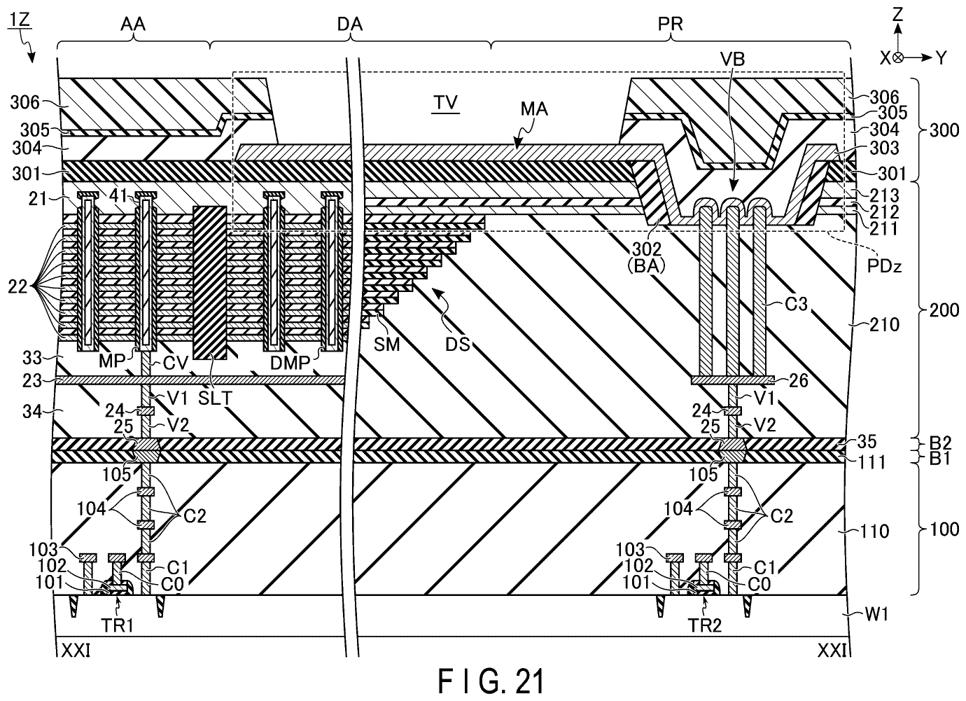

FIG. 21 is a cross-sectional view taken along line XXI-XXI of FIG. 20, showing an example of a cross-sectional structure of the vicinity of the pad unit PDz in the memory device 1Z according to the second comparative example. As shown in FIG. 21, in the memory device 1Z, the via TV is placed to overlap with the dummy area DA (for example, the dummy staircase portion DS). On the other hand, in the memory device 1Z, unlike in the first embodiment, the conductive layer 21 or the conductive layers 211 and 213 are placed in a portion facing the via TV in the Z direction. Thus, in the memory device 1Z, the chip size can be made smaller than in the first comparative example, but on the other hand the parasitic capacitance between the conductive portion MA and the source line SL can be increased. Thus, in the second comparative example, the interface speed may be poorer than in the first comparative example.

In contrast, the memory device 1 according to the first embodiment has a structure in which the source line SL in an area where an end portion of the memory cell array 10 (the dummy area DA) and the pad unit PD overlap is removed and the insulating member 302 is embedded in the area. Specifically, in the memory device 1 according to the first embodiment, the memory layer 200 includes a layer stack including an insulating layer 32 and a conductive layer 22 alternately stacked in the Z direction in the active area AA and including a sacrificial member SM provided in the same layer as the conductive layer 22 in the dummy area DA, a plurality of memory pillars MP and a plurality of dummy pillars DMP penetrating the layer stack, and a source line SL (a conductive layer 21) connected to the memory pillars MP above the layer stack. A pad (a via TV) corresponding to part of the conductive portion MA exposed in the via TV has a portion overlapping with the sacrificial member SM in the Z direction, and does not have a portion overlapping with the source line SL in the Z direction.

Thereby, in the memory device 1 according to the first embodiment, the parasitic capacitance between the conductive portion MA and the source line SL, that is, the parasitic capacitance of the pad can be reduced. Further, the chip size of the memory device 1 according to the first embodiment can be reduced like in the second comparative example by having a portion where the pad unit PD and the dummy area DA overlap in the Z direction. Therefore, the memory device 1 according to the first embodiment can reduce the chip size while suppressing degradation in interface speed.

### <2> Second Embodiment

A memory device 1A according to a second embodiment has a structure in which a contact VBP penetrating the insulating member 302 is formed in place of the via VB described in the first embodiment and the conductive layer 303 and the contact C3 are electrically connected to each other via the contact VBP. Details of the memory device 1A according to the second embodiment will now be described.

### <2-1> Configuration

The memory device 1A according to the second embodiment has a similar configuration to the memory device 1 according to the first embodiment except for the structure of the pad unit PD. A planar layout and a cross-sectional structure of a pad unit PDa in the memory device 1A according to the second embodiment will now be described.

### <2-1-1> Planar Layout of the Pad Unit PDa

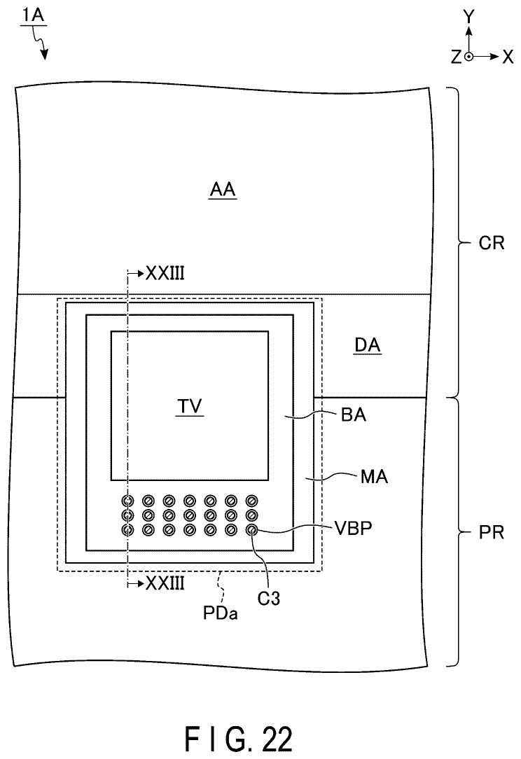

FIG. 22 is a plan view showing an example of a planar layout of the vicinity of the pad unit PDa in the memory device 1A according to the second embodiment. FIG. 22 shows a pad unit PDa used for connection to the input/output circuit 11, the logic controller 12, or the like in the memory device 1A, and part of each of the core area CR and the peripheral area PR.

As shown in FIG. 22, the pad unit PDa overlaps with each of the core area CR and the peripheral area PR. The pad unit PDa has a portion overlapping with the dummy area DA of the core area CR, and does not have a portion overlapping with the active area AA. The pad unit PDa includes a conductive portion MA, an insulating portion BA, a via TV, and a plurality of contacts VBP.

The configurations of the conductive portion MA, the insulating portion BA, and the via TV in the pad unit PDa are similar to those of the pad unit PD of the first embodiment. Each of the contacts VBP is included in the peripheral area PR, and is provided to penetrate part of the insulating portion BA. The area where the contacts VBP are formed is adjacent to the via TV in the Y direction, and is placed not to overlap with the via TV. The contacts VBP are arranged in a lattice configuration, for example. The contacts VBP individually overlap with the contacts C3. A set of contact VBP and contact C3 arranged to overlap are electrically connected to each other.

### <2-1-2> Cross-Sectional Structure of the Pad Unit PDa

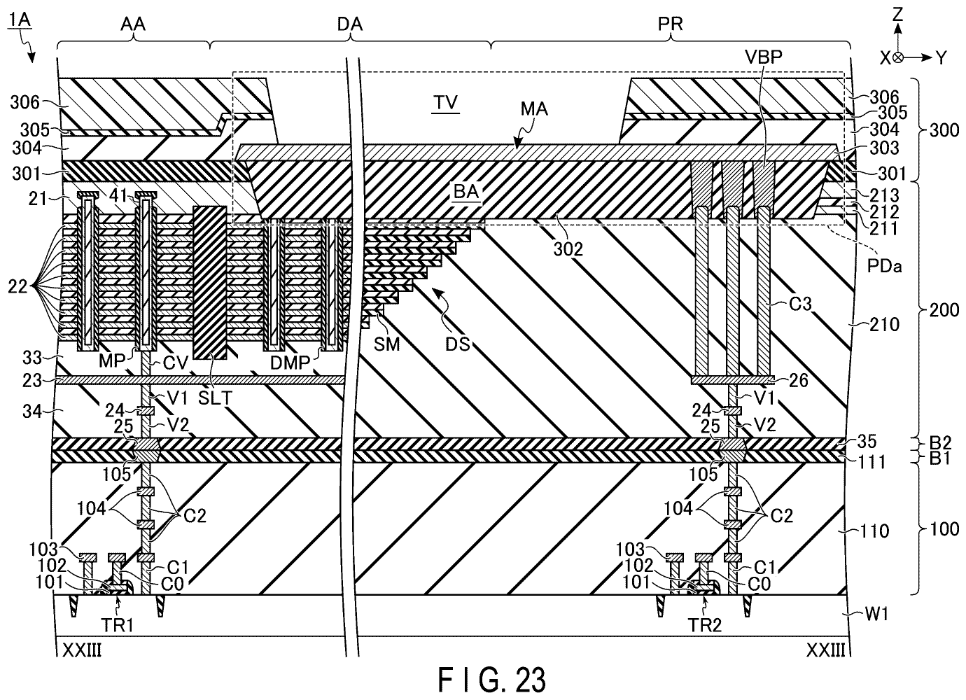

FIG. 23 is a cross-sectional view taken along line XXIII-XXIII of FIG. 22, showing an example of a cross-sectional structure of the vicinity of the pad unit PDa in the memory device 1A according to the second embodiment. As shown in FIG. 23, the pad unit PDa has a configuration in which, in the pad unit PD described using FIG. 11 in the first embodiment, the via VB is omitted and a plurality of contacts VBP are added. Each of the contacts VBP is provided to penetrate the insulating member 302 corresponding to the insulating portion BA. Bottom portions of the contacts VBP are individually connected to upper portions of the contacts C3 provided to overlap in the Z direction. In the pad unit PDa, the upper surface of the insulating member 302, the upper surface of the contact VBP, and the upper surface of the insulating layer 301 are aligned.

The conductive layer 303 corresponding to the conductive portion MA is provided on the planarized upper surfaces of the insulating member 302 and the contacts VBP. The conductive portion MA of the second embodiment does not have a level difference in the boundary portion between the insulating layer 301 and the insulating member 302. The configuration of the other parts of the pad unit PDa is similar to that of the pad unit PD in the first embodiment.

### <2-2> Manufacturing Method

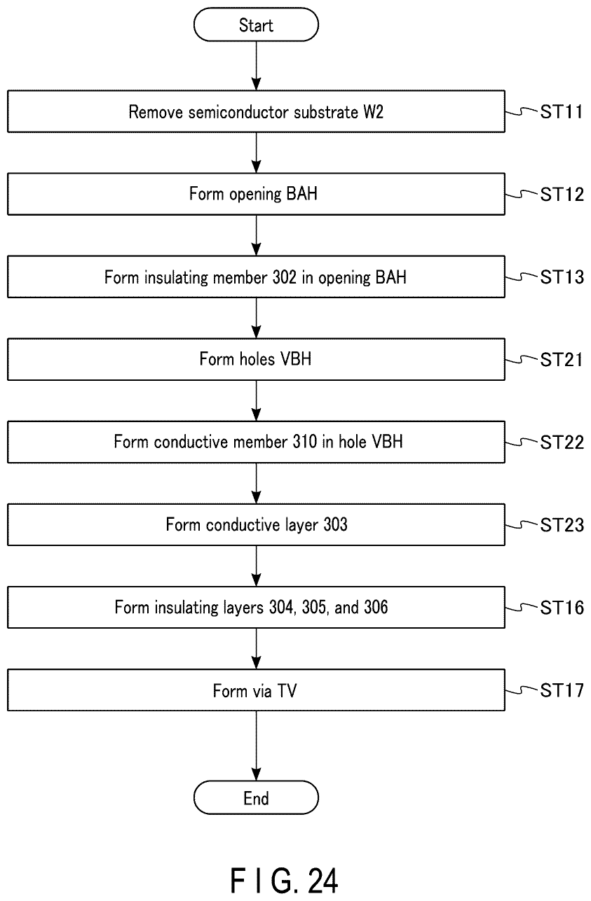

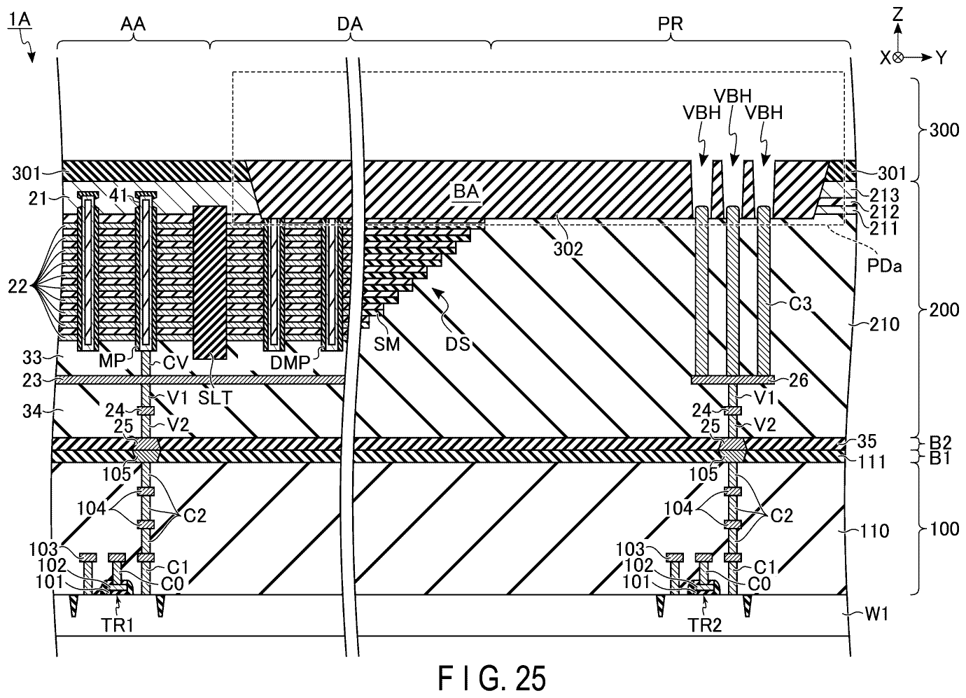

Next, as a method of manufacturing the memory device 1A according to the second embodiment, a method of forming the pad unit PDa after bonding the semiconductor substrate W1 and the semiconductor substrate W2 is described with reference to FIG. 24 as appropriate. FIG. 24 is a flowchart showing an example of a method of manufacturing the memory device 1A according to the second embodiment. Each of FIGS. 25 to 27 is a cross-sectional view showing an example of a cross-sectional structure in the manufacturing process of the memory device 1A according to the second embodiment, and shows a cross section including the vicinity of the pad unit PDa.

First, like in the first embodiment, the semiconductor substrate W2 is removed (step ST11), an opening BAH is formed (step ST12), and an insulating member 302 is formed in the opening BAH (step ST13).

Next, as shown in FIG. 25, a plurality of holes VBH are formed (step ST21). Specifically, first, a mask in which a portion overlapping with each contact C3 is opened in a planar view is formed. After that, anisotropic etching processing is executed to remove the insulating member 302 in the openings of the mask, and a plurality of holes VBH are formed. At the bottom of each hole VBH, an upper portion of the associated contact C3 is exposed.

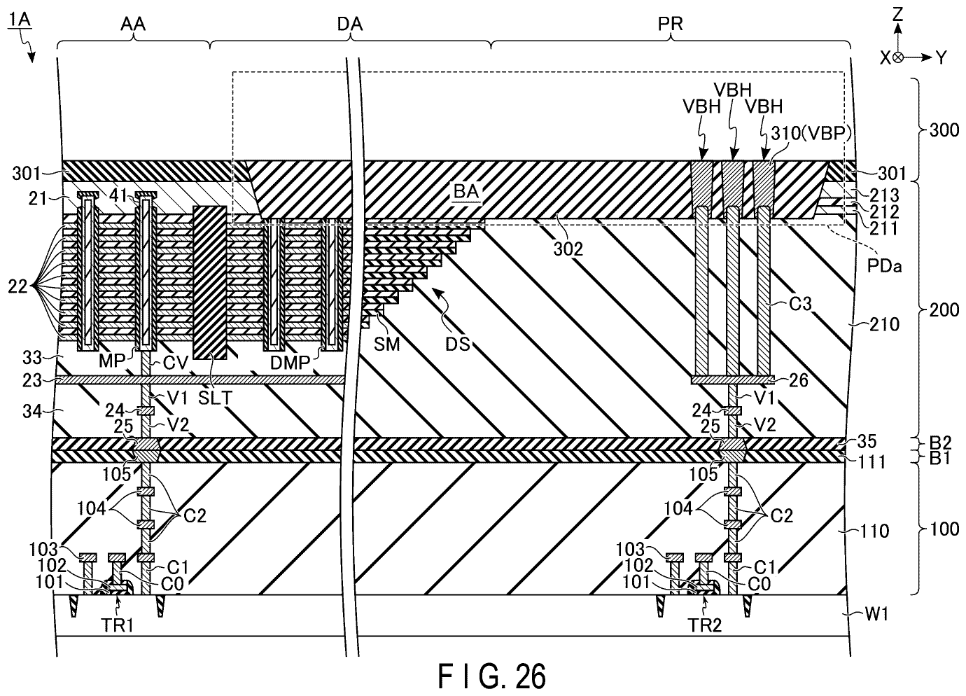

Next, as shown in FIG. 26, a conductive member 310 is formed in each hole VBH (step ST22). Specifically, first, a conductive member 310 is formed by CVD or the like such that each hole VBH is filled. After that, for example, the conductive member 310 formed outside each hole VBH is removed by CMP processing, and a plurality of contacts VBP are formed. By this CMP processing, the upper surface of the conductive member 310 (the contact VBP) in each hole VBH, the upper surface of the insulating member 302, and the upper surface of the insulating layer 301 are aligned.

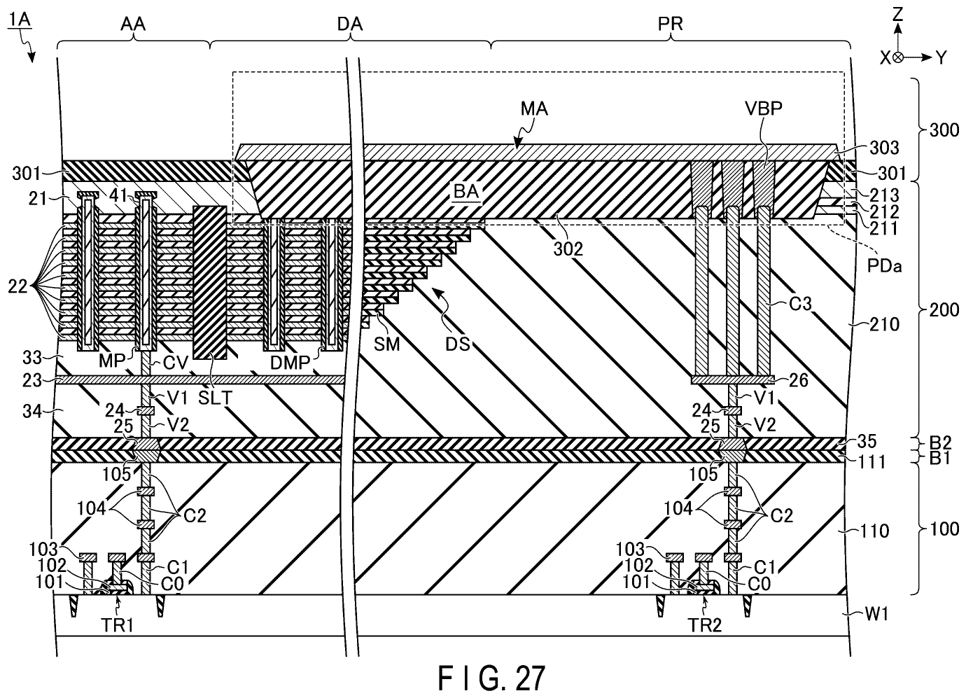

Next, as shown in FIG. 27, a conductive layer 303 is formed (step ST23). Specifically, for example, first, a conductive layer 303 is formed, and a mask that covers the portion of a conductive portion MA is formed. After that, anisotropic etching processing is executed to process the conductive layer 303 into the shape of the conductive portion MA.

After that, like in the first embodiment, insulating layers 304, 305, and 306 are formed (step ST16), and a via TV is formed (step ST17). Thereby, a structure corresponding to the pad unit PDa shown in FIG. 23 is completed.

### <2-3> Advantageous Effects of the Second Embodiment

Like in the first embodiment, the memory device 1A according to the second embodiment has a structure in which the structure corresponding to the source line SL is removed in the dummy area DA, and the dummy area DA and the pad unit PDa overlap in the Z direction. Therefore, like in the first embodiment, the memory device 1A according to the second embodiment can reduce the parasitic capacitance of the pad, and can reduce the chip size while suppressing degradation in interface speed.

Further, the memory device 1A according to the second embodiment uses the contact VBP for connection between the conductive portion MA and the contact C3 instead of using the via VB as in the first embodiment. Then, in the memory device 1A, at the time of forming the contact VBP, the upper surfaces of the insulating portion BA and the contact VBP are planarized. As a result, the memory device 1A according to the second embodiment can suppress the occurrence of defects that might occur due to level differences of the conductive portion MA formed along the via VB as in the first embodiment. Therefore, the memory device 1A according to the second embodiment can improve the yield more than in the first embodiment.

### <3> Third Embodiment

A memory device 1B according to a third embodiment has a structure in which a conductive member 320 is formed to cover upper portions of the contacts C3 described in the first embodiment, and the conductive layer 303 and each contact C3 are electrically connected to each other via the conductive member 320. Details of the memory device 1B according to the third embodiment will now be described.

### <3-1> Configuration

The memory device 1B according to the third embodiment has a similar configuration to the memory device 1 according to the first embodiment except for the structure of the pad unit PD. A planar layout and a cross-sectional structure of a pad unit PDb in the memory device 1B according to the third embodiment will now be described.

### <3-1-1> Planar Layout of the Pad Unit PDb

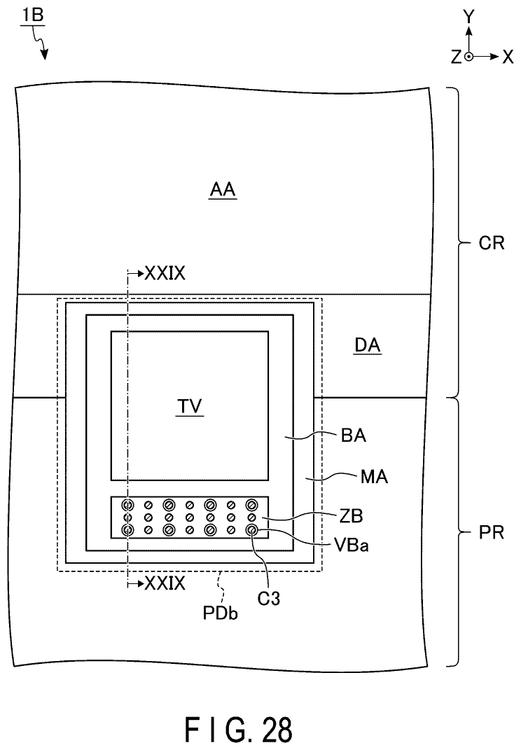

FIG. 28 is a plan view showing an example of a planar layout of the vicinity of the pad unit PDb in the memory device 1B according to the third embodiment. FIG. 28 shows a pad unit PDb used for connection to the input/output circuit 11, the logic controller 12, or the like in the memory device 1B, and part of each of the core area CR and the peripheral area PR.

As shown in FIG. 28, the pad unit PDb overlaps with each of the core area CR and the peripheral area PR. The pad unit PDb has a portion overlapping with the dummy area DA of the core area CR, and does not have a portion overlapping with the active area AA. The pad unit PDb includes a conductive portion MA, an insulating portion BA, a via TV, a conductive portion ZB, and a plurality of vias VBa.

The configurations of the conductive portion MA, the insulating portion BA, and the via TV in the pad unit PDb are similar to those of the pad unit PD of the first embodiment. The conductive portion ZB is included in the peripheral area PR, and is placed to overlap with each of the conductive portion MA and the insulating portion BA. Further, the conductive portion ZB is adjacent to the via TV in the Y direction, and is placed not to overlap with the via TV. The conductive portion ZB is connected to each of the contacts C3 to be electrically connected to the conductive portion MA. Each of the vias VBa is placed to overlap with the conductive portion ZB in a planar view, and is provided to penetrate part of the insulating portion BA. The vias VBa are arranged in a lattice configuration, for example. The conductive portion MA is electrically connected to the conductive portion ZB via the vias VBa. That is, the conductive portion MA is electrically connected to the contacts C3 via the conductive portion ZB.

### <3-1-2> Cross-Sectional Structure of the Pad Unit PDb

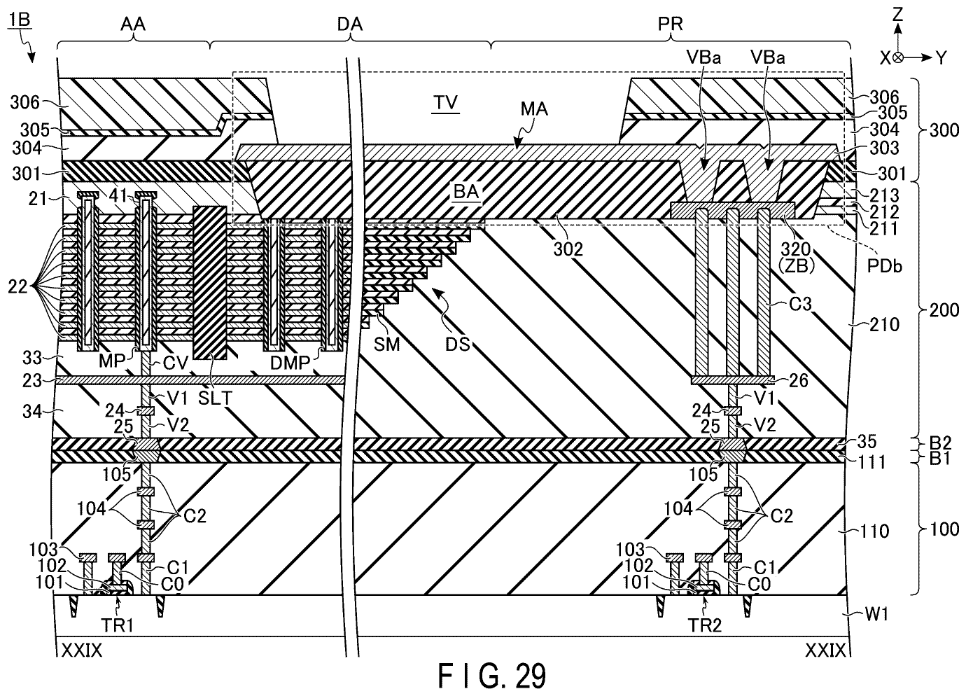

FIG. 29 is a cross-sectional view taken along line XXIX-XXIX of FIG. 28, showing an example of a cross-sectional structure of the vicinity of the pad unit PDb in the memory device 1B according to the third embodiment. As shown in FIG. 29, the pad unit PDb has a configuration in which, in the pad unit PD described using FIG. 11 in the first embodiment, the via VB is replaced with a plurality of vias VBa and a conductive portion ZB is added. The conductive member 320 corresponding to the conductive portion ZB is provided to cover upper portions of the contacts C3. An upper portion of the conductive member 320 has a portion covered with the insulating member 302 corresponding to the insulating portion BA. The vias VBa penetrate the insulating member 302. The bottom of each of the vias VBa reaches the conductive member 320.

The conductive layer 303 corresponding to the conductive portion MA is provided on the insulating member 302, and has a portion provided along the vias VBa. The conductive layer 303 fills the vias VBa, and is connected to the conductive member 320 in bottom portions of the vias VBa. Then, the conductive layer 303 is electrically connected to the contacts C3 via the conductive member 320, and is electrically connected to the transistor TR2 via the contacts C3. The conductive layer 303 may have a recessed portion in an upper portion of the via VBa. The configuration of the other parts of the pad unit PDb is similar to that of the pad unit PD in the first embodiment.

### <3-2> Manufacturing Method

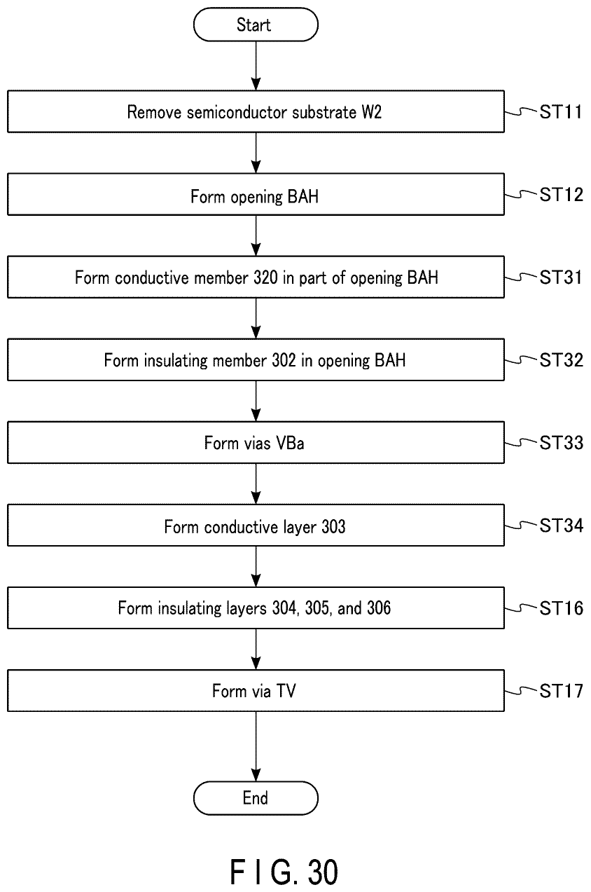

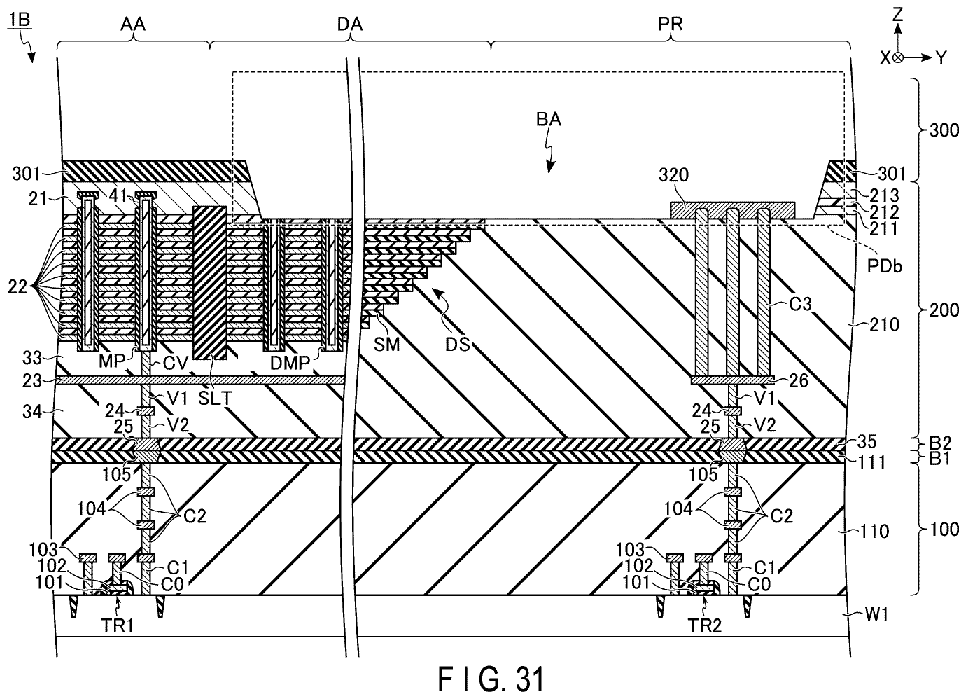

Next, as a method of manufacturing the memory device 1B according to the third embodiment, a method of forming the pad unit PDb after bonding the semiconductor substrate W1 and the semiconductor substrate W2 is described with reference to FIG. 30 as appropriate. FIG. 30 is a flowchart showing an example of a method of manufacturing the memory device 1B according to the third embodiment. Each of FIGS. 31 to 34 is a cross-sectional view showing an example of a cross-sectional structure in the manufacturing process of the memory device 1B according to the third embodiment, and shows a cross section including an area in the vicinity of the pad unit PDb.

First, like in the first embodiment, the semiconductor substrate W2 is removed (step ST11), and an opening BAH is formed (step ST12).

Next, as shown in FIG. 31, a conductive member 320 is formed in part of the opening BAH (step ST31). Specifically, for example, first, a conductive member 320 is formed by CVD or the like, and a mask that covers the portion of a conductive portion ZB is formed. After that, anisotropic etching processing is executed to process the conductive member 320 into the shape of the conductive portion ZB.

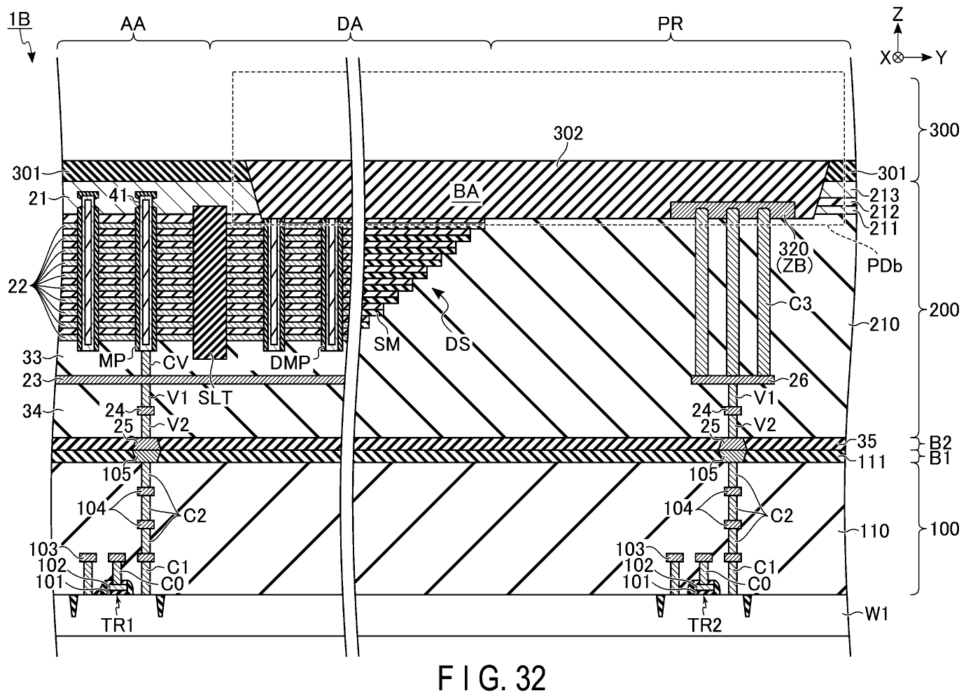

Next, as shown in FIG. 32, an insulating member 302 is formed in the opening BAH (step ST32). Specifically, first, an insulating member 302 is formed such that the opening BAH is filled. Then, for example, the insulating member 302 formed outside the opening BAH is removed by CMP processing. The insulating member 302 remaining in the opening BAH corresponds to the insulating portion BA. In the CMP processing in step ST32, a level difference may remain between the insulating layer 301 and the insulating member 302.

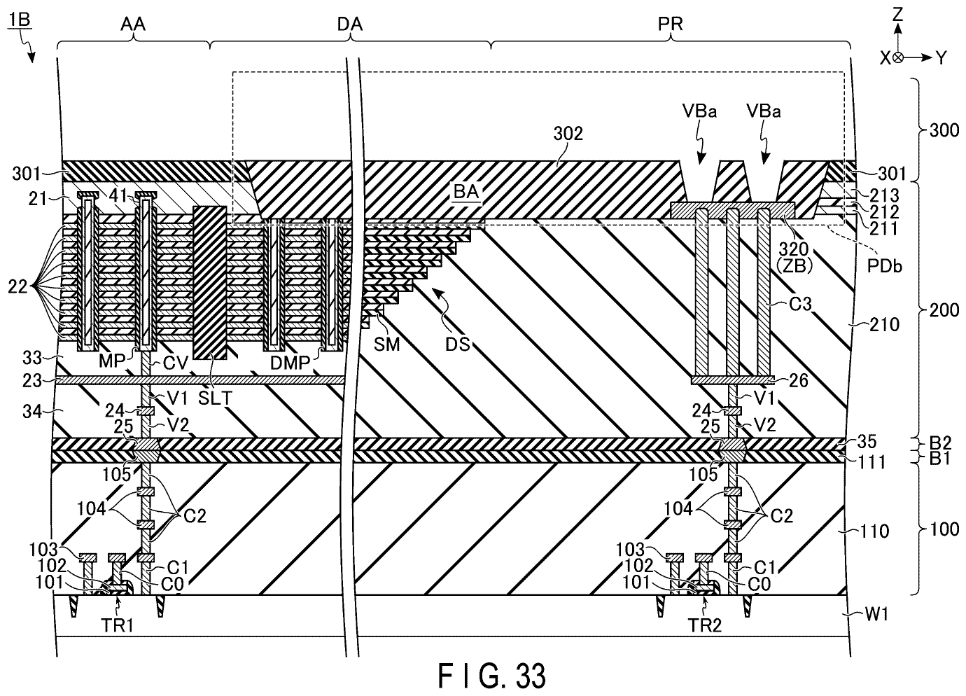

Next, as shown in FIG. 33, vias VBa are formed (step ST33). Specifically, first, a mask in which the portions of vias VBa are opened in a planar view is formed. After that, the insulating member 302 is removed in the openings of the mask by anisotropic etching processing, and vias VBa are formed. In the via VBa, an upper portion of the conductive portion ZB is exposed.

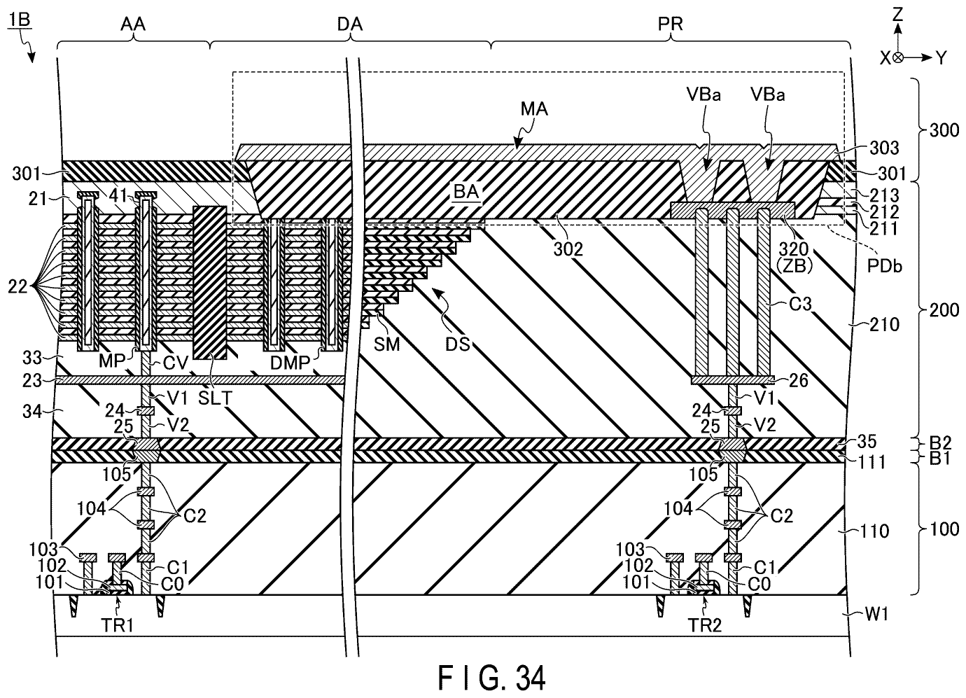

Next, as shown in FIG. 34, a conductive layer 303 is formed (step ST34). Specifically, for example, first, a conductive layer 303 is formed by CVD or the like such that the via VBa is filled, and a mask that covers the portion of a conductive portion MA is formed. After that, anisotropic etching processing is executed to process the conductive layer 303 into the shape of the conductive portion MA.

After that, like in the first embodiment, insulating layers 304, 305, and 306 are formed (step ST16), and a via TV is formed (step ST17). Thereby, a structure corresponding to the pad unit PDb shown in FIG. 29 is completed.

### <3-3> Advantageous Effects of the Third Embodiment

Like in the first embodiment, the memory device 1B according to the third embodiment has a structure in which the structure corresponding to the source line SL is removed in the dummy area DA, and the dummy area DA and the pad unit PDb overlap in the Z direction. Therefore, like in the first embodiment, the memory device 1B according to the third embodiment can reduce the parasitic capacitance of the pad, and can reduce the chip size while suppressing degradation in interface speed.

Further, in the memory device 1B according to the third embodiment, the conductive portion MA and the contact C3 are connected to each other via the conductive portion ZB. Thereby, the conductive layer 303 and the contact C3 can be more reliably electrically connected to each other than in a case where the conductive layer 303 is directly connected to a protruding portion of the contact C3. Therefore, the memory device 1B according to the third embodiment can improve the yield more than in the first embodiment.

### <4> Fourth Embodiment

A memory device 1C according to a fourth embodiment has a structure in which, in the memory device 1A according to the second embodiment, an area where contacts VBP and C3 are formed and an area where a via TV is formed overlap in the Z direction. Details of the memory device 1C according to the fourth embodiment will now be described.

### <4-1> Configuration

The memory device 1C according to the fourth embodiment has a similar configuration to the memory device 1A according to the second embodiment except for the structure of the pad unit PDa. A planar layout and a cross-sectional structure of a pad unit PDc in the memory device 1C according to the fourth embodiment will be described.

### <4-1-1> Planar Layout of the Pad Unit PDc

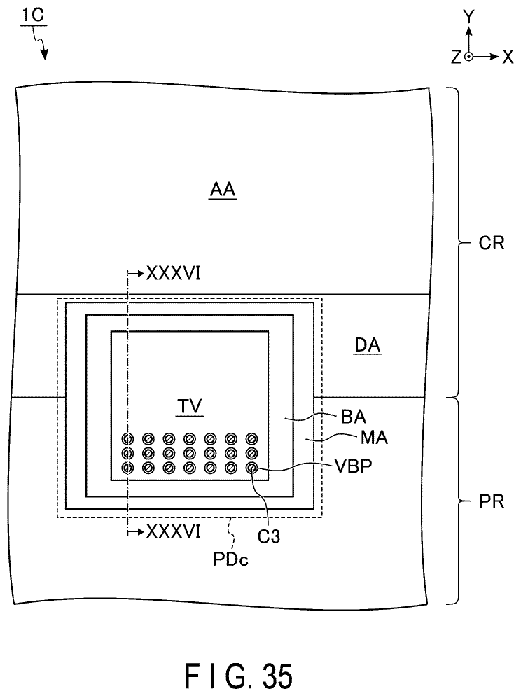

FIG. 35 is a plan view showing an example of a planar layout of the vicinity of the pad unit PDc in the memory device 1C according to the fourth embodiment. FIG. 35 shows a pad unit PDc used for connection to the input/output circuit 11, the logic controller 12, or the like in the memory device 1C, and part of each of the core area CR and the peripheral area PR.

As shown in FIG. 35, the pad unit PDc overlaps with each of the core area CR and the peripheral area PR. The pad unit PDc has a portion overlapping with the dummy area DA of the core area CR, and does not have a portion overlapping with the active area AA. The pad unit PDC includes a conductive portion MA, an insulating portion BA, a via TV, and a plurality of contacts VBP.

The configurations of the conductive portion MA, the insulating portion BA, and the via TV in the pad unit PDC are similar to those of the pad unit PDa of the second embodiment. Each of the contacts VBP is included in the peripheral area PR, and is provided to penetrate part of the insulating portion BA. An area where the contacts VBP are formed overlaps with the via TV in a planar view. The contacts VBP individually overlap with the contacts C3. A set of contact VBP and contact C3 arranged to overlap are electrically connected to each other.

### <4-1-2> Cross-Sectional Structure of the Pad Unit PDC

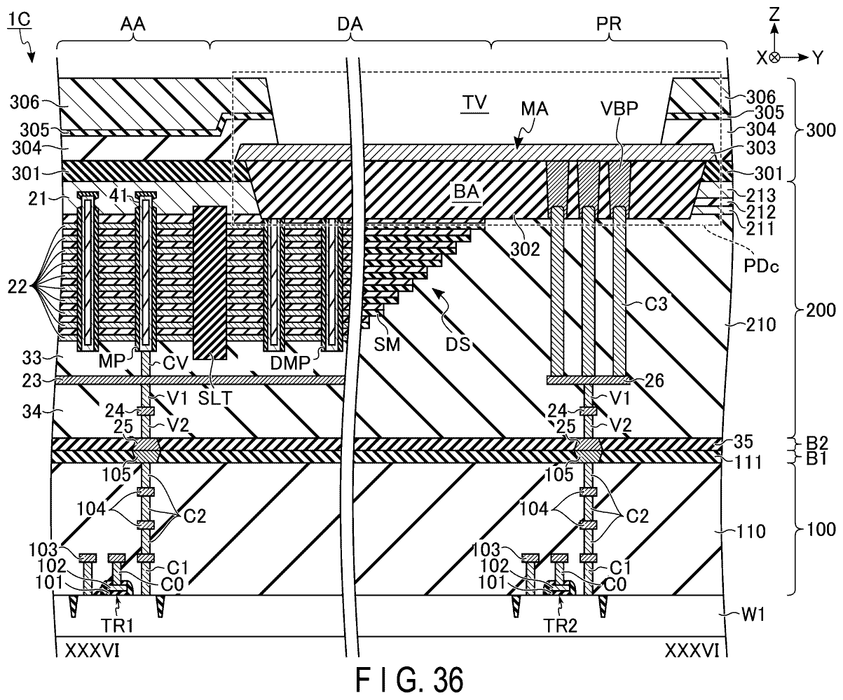

FIG. 36 is a cross-sectional view taken along line XXXVI-XXXVI of FIG. 35, showing an example of a cross-sectional structure of the vicinity of the pad unit PDC in the memory device 1C according to the fourth embodiment. As shown in FIG. 36, the pad unit PDc has a configuration in which, in the pad unit PDa described using FIG. 23 in the second embodiment, a plurality of contacts VBP and a via TV are arranged to overlap in the Z direction. Thus, the pad unit PDc of the fourth embodiment can be designed to be smaller than the pad unit PDa of the second embodiment. The configuration of the other parts of the pad unit PDc is similar to that of the pad unit PDa in the second embodiment.

### <4-2> Manufacturing Method

A method of manufacturing the memory device 1C according to the fourth embodiment is similar to a method in which, in the method of manufacturing the memory device 1A according to the second embodiment described using FIGS. 24 to 27, a change is made such that an area where the contacts VBP and C3 are formed and an area where the via TV is formed are arranged to overlap in the Z direction.

### <4-3> Advantageous Effects of the Fourth Embodiment

Like in the first embodiment, the memory device 1C according to the fourth embodiment has a structure in which the structure corresponding to the source line SL is removed in the dummy area DA, and the dummy area DA and the pad unit PDc overlap in the Z direction. Therefore, like in the first embodiment, the memory device 1C according to the fourth embodiment can reduce the parasitic capacitance of the pad, and can reduce the chip size while suppressing degradation in interface speed.

Further, in the memory device 1C according to the fourth embodiment, the via TV and the contacts VBP are arranged to overlap in the Z direction. Thereby, the memory device 1C according to the fourth embodiment can suppress the chip area more than the memory device 1A according to the second embodiment. As a result, the memory device 1C according to the fourth embodiment can suppress the manufacturing cost more than the memory device 1A according to the second embodiment.

### <5> Fifth Embodiment

A memory device 1D according to a fifth embodiment has a structure in which, in the memory device 1B according to the third embodiment, an area where the contacts C3 and the conductive member 320 are formed and an area where the via TV is formed overlap in the Z direction. Details of the memory device 1D according to the fifth embodiment will now be described.

### <5-1> Configuration

The memory device 1D according to the fifth embodiment has a similar configuration to the memory device 1B according to the third embodiment except for the structure of the pad unit PDb. A planar layout and a cross-sectional structure of a pad unit PDd in the memory device 1D according to the fifth embodiment will now be described.

### <5-1-1> Planar Layout of the Pad Unit PDd

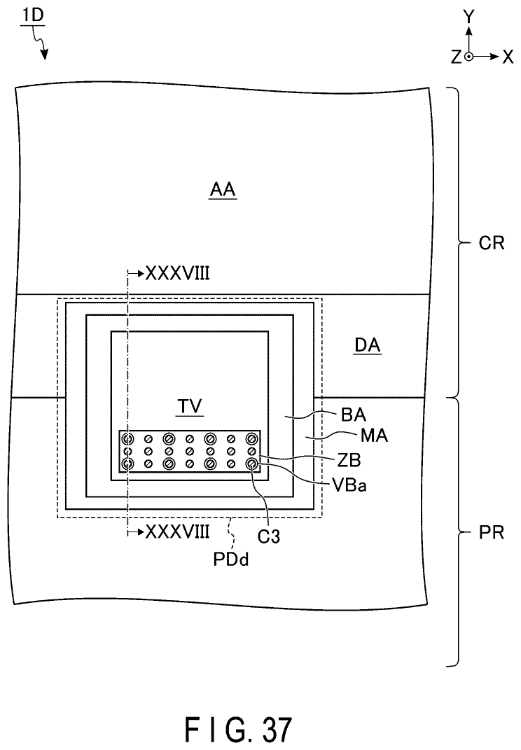

FIG. 37 is a plan view showing an example of a planar layout of the vicinity of the pad unit PDd in the memory device 1D according to the fifth embodiment. FIG. 37 shows a pad unit PDd used for connection to the input/output circuit 11, the logic controller 12, or the like in the memory device 1D, and part of each of the core area CR and the peripheral area PR.

As shown in FIG. 37, the pad unit PDd overlaps with each of the core area CR and the peripheral area PR. The pad unit PDd has a portion overlapping with the dummy area DA of the core area CR, and does not have a portion overlapping with the active area AA. The pad unit PDd includes a conductive portion MA, an insulating portion BA, a via TV, a conductive portion ZB, and a plurality of vias VBa.

The configurations of the conductive portion MA, the insulating portion BA, and the via TV in the pad unit PDd are similar to those of the pad unit PDb of the third embodiment. The conductive portion ZB is included in the peripheral area PR, and is placed to overlap with each of the conductive portion MA and the insulating portion BA. The conductive portion ZB overlaps with the via TV in a planar view. The conductive portion ZB is connected to each of the contacts C3 to be electrically connected to the conductive portion MA. Each of the vias VBa is placed to overlap with the conductive portion ZB in a planar view, and is provided to penetrate part of the insulating portion BA. The conductive portion MA is electrically connected to the conductive portion ZB via the vias VBa. That is, the conductive portion MA is electrically connected to the contacts C3 via the conductive portion ZB.

### <5-1-2> Cross-Sectional Structure of the Pad Unit PDd

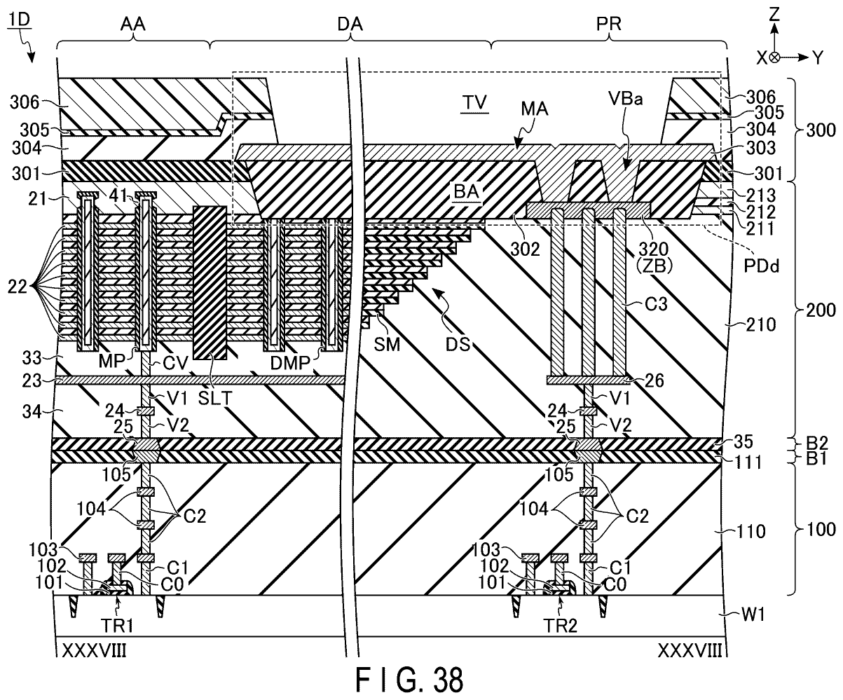

FIG. 38 is a cross-sectional view taken along line XXXVIII-XXXVIII of FIG. 37, showing an example of a cross-sectional structure of the vicinity of the pad unit PDd in the memory device 1D according to the fifth embodiment. As shown in FIG. 38, the pad unit PDd has a configuration in which, in the pad unit PDb described using FIG. 29 in the third embodiment, the conductive portion ZB and the via TV are arranged to overlap in the Z direction. Thus, the pad unit PDd of the fifth embodiment can be designed to be smaller than the pad unit PDb of the third embodiment. The configuration of the other parts of the pad unit PDd is similar to that of the pad unit PDb in the third embodiment.

### <5-2> Manufacturing Method

A method of manufacturing the memory device 1D according to the fifth embodiment is similar to a method in which, in the method of manufacturing the memory device 1B according to the third embodiment described using FIGS. 30 to 34, a change is made such that an area where the conductive portion ZB and the contacts C3 are formed and an area where the via TV is formed are arranged to overlap in the Z direction.

### <5-3> Advantageous Effects of the Fifth Embodiment

Like in the first embodiment, the memory device 1D according to the fifth embodiment has a structure in which the structure corresponding to the source line SL is removed in the dummy area DA, and the dummy area DA and the pad unit PDd overlap in the Z direction. Therefore, like in the first embodiment, the memory device 1D according to the fifth embodiment can reduce the parasitic capacitance of the pad, and can reduce the chip size while suppressing degradation in interface speed.

Further, in the memory device 1D according to the fifth embodiment, the via TV and the conductive portion ZB are arranged to overlap in the Z direction. Thereby, the memory device 1D according to the fifth embodiment can suppress the chip area more than the memory device 1B according to the third embodiment. As a result, the memory device 1D according to the fifth embodiment can suppress the manufacturing cost more than the memory device 1B according to the third embodiment.

### <6> Sixth Embodiment

A sixth embodiment relates to a memory device in which a source line SL of a different structure is used for the memory device 1 according to the first embodiment. Details of a memory device 1E according to the sixth embodiment will now be described.

### <6-1> Configuration

The memory device 1E according to the sixth embodiment has a similar configuration to the memory device 1 according to the first embodiment except for the structure of the source line SL. A cross-sectional structure of the memory cell array 10 and a planar layout and a cross-sectional structure of the pad unit PD in the memory device 1E according to the sixth embodiment will now be described.

### <6-1-1> Cross-Sectional Structure of the Memory Cell Array 10

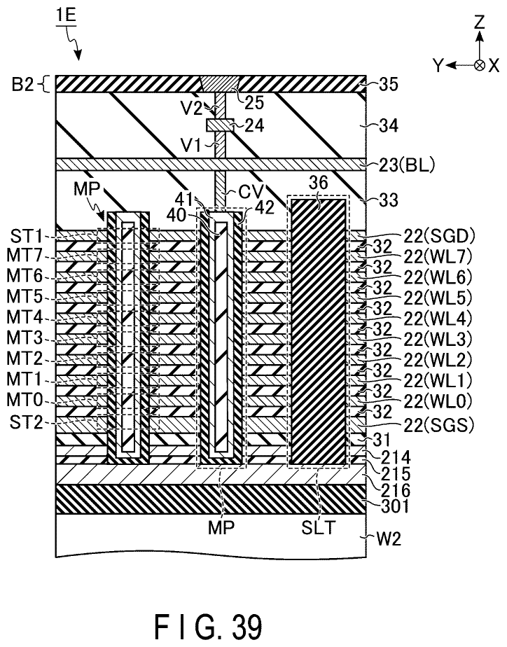

FIG. 39 is a cross-sectional view showing an example of a cross-sectional structure of a memory cell array 10 included in the memory device 1E according to the sixth embodiment. FIG. 39 shows an example of a structure of a memory cell array 10 formed on the semiconductor substrate W2 before being bonded to the semiconductor substrate W1, and shows coordinate axes with the semiconductor substrate W2 as a reference. The area shown in FIG. 39 corresponds to a similar area to FIG. 6 described in the first embodiment. As shown in FIG. 39, in the memory device 1E, the memory cell array 10 formed on the semiconductor substrate W2 before being bonded to the semiconductor substrate W1 has, for example, a structure in which, with respect to the memory cell array 10 of the first embodiment, the conductive layer 21 is replaced with a semiconductor layer 214, a member 215, and a semiconductor layer 216.

The semiconductor layer 216 is, for example, provided on the semiconductor substrate W2 via an insulating layer 301. The member 215 is provided on the semiconductor layer 216. The semiconductor layer 214 is provided on the member 215. The insulating layer 31 is provided on the semiconductor layer 214. Each of the semiconductor layers 214 and 216 is, for example, amorphous silicon. The semiconductor layer 216 is used as, for example, an etching stopper layer at the time of forming the memory pillar MP or the slit SLT. For example, each of the memory pillar MP and the slit SLT penetrates the semiconductor layer 214. The bottom of each of the memory pillar MP and the slit SLT reaches the semiconductor layer 216. The structure of the other parts of the memory cell array 10 of the sixth embodiment is similar to that of the memory cell array 10 of the first embodiment.

### <6-1-2> Planar Layout of the Pad Unit PD

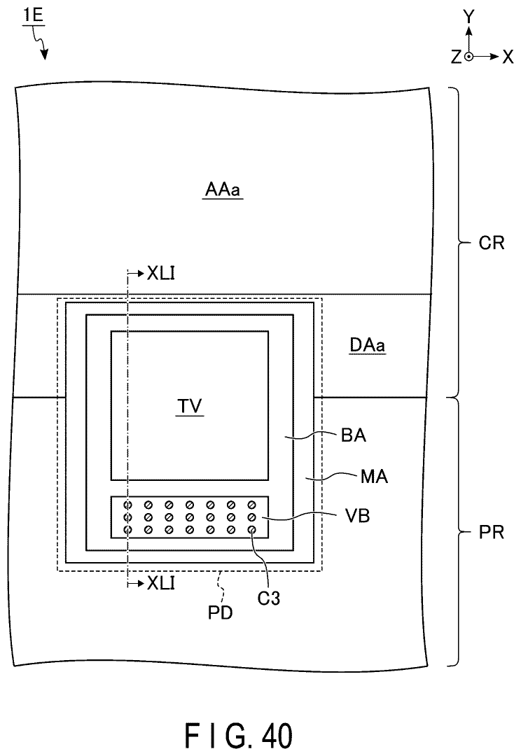

FIG. 40 is a plan view showing an example of a planar layout of the vicinity of the pad unit PD in the memory device 1E according to the sixth embodiment. FIG. 40 shows a pad unit PD used for connection to the input/output circuit 11, the logic controller 12, or the like in the memory device 1E, and part of each of the core area CR and the peripheral area PR.

As shown in FIG. 40, the memory device 1E has a configuration in which, in the memory device 1 according to the first embodiment, the active area AA and the dummy area DA of the core area CR are replaced with an active area AAa and a dummy area DAa, respectively. In the active area AAa and the dummy area DAa, the structures of portions corresponding to the source line SL are different than in the active area AA and the dummy area DA, respectively. Details of the structure of the source line SL in the memory device 1E will be described later. The pad unit PD of the sixth embodiment overlaps with each of the core area CR and the peripheral area PR. The pad unit PD of the sixth embodiment has a portion overlapping with the dummy area DAa of the core area CR, and does not have a portion overlapping with the active area AAa. Similarly to the pad unit PD of the first embodiment, the pad unit PD of the sixth embodiment includes a conductive portion MA, an insulating portion BA, a via TV, and a via VB.

### <6-1-3> Cross-Sectional Structure of the Vicinity of the Pad Unit PD

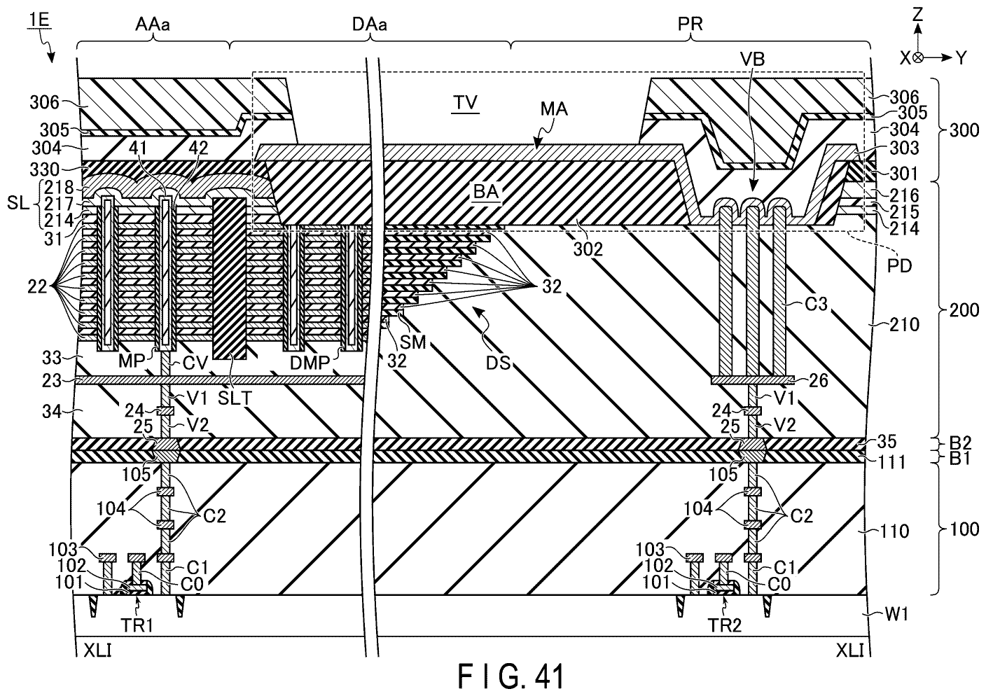

FIG. 41 is a cross-sectional view taken along line XLI-XLI of FIG. 40, showing an example of a cross-sectional structure of the vicinity of the pad unit PD in the memory device 1E according to the sixth embodiment. FIG. 41 shows parts of the active area AAa, the dummy area DAa, and the peripheral area PR after the semiconductor substrate W1 and the semiconductor substrate W2 are bonded together and the wiring layer 300 is formed, and shows coordinate axes with the semiconductor substrate W1 as a reference. In the memory device 1E, the structure in the wall area WR is similar to that in the peripheral area PR, and thus a description of the structure in the wall area WR is omitted.

As shown in FIG. 41, in the memory device 1E, the stacked film 42 in an upper portion of the memory pillar MP is removed. Further, the stacked film 42 in an upper portion of the dummy pillar DMP is removed. In the active area AAa, the dummy area DAa, and the peripheral area PR, a semiconductor layer 214 is provided on the layer stack corresponding to the memory cell array 10 or on the insulating layer 210. On the semiconductor layer 214, a member 215, a semiconductor layer 216, and an insulating layer 301 are provided in this order in the peripheral area PR and a portion of the dummy area DAa on the peripheral area PR side. Further, on the semiconductor layer 214, a semiconductor layer 217, a conductive layer 218, and an insulating layer 330 are provided in this order in the active area AAa and a portion of the dummy area DAa on the active area AAa side.

Each of the semiconductor layers 214, 216, and 217 is, for example, polysilicon. The semiconductor layer 217 is doped with an impurity. Thus, the semiconductor layer 217 functions as a conductor. At the time of doping the semiconductor layer 217 with an impurity, the impurity can diffuse to the semiconductor layer 214 in the active area AAa. Thus, the semiconductor layer 214 in the active area AAa can contain the impurity, and can function as a conductor. On the other hand, at the time of doping the semiconductor layer 217 with an impurity, the peripheral area PR is excluded from the area to be doped with the impurity. Thus, the semiconductor layer 214 in the peripheral area PR does not contain such an impurity.

The semiconductor layer 217 is provided to cover the semiconductor layer 41 in an upper portion of each memory pillar MP, the semiconductor layer 41 in an upper portion of each dummy pillar DMP (not illustrated), and an upper portion of the slit SLT. Thus, each of the conductive layer 217 and the conductive layer 218 has a portion provided along an upper portion of each of the memory pillar MP, the dummy pillar DMP, and the slit SLT. Then, the semiconductor layer 217 is electrically connected to the semiconductor layer 41 of each memory pillar MP. In the memory device 1E, a set of the semiconductor layers 214 and 217 and the conductive layer 218 functions as part of the source line SL. The upper surface of the insulating layer 330 is aligned with, for example, the upper surface of the insulating layer 301 in the peripheral area PR.

The insulating member 302 of the memory device 1E is provided to penetrate, in part of the peripheral area PR, the insulating layer 301, the semiconductor layer 216, the member 215, and the semiconductor layer 214. Further, the insulating member 302 is provided to penetrate, in part of the dummy area DAa, the insulating layer 330, the conductive layer 218, the semiconductor layer 217, and the semiconductor layer 214. The upper surface of the insulating member 302 may be aligned with the upper surfaces of the insulating layers 301 and 330, or level differences may be formed between the insulating member 302 and the insulating layers 301 and 330. The lower surface of the insulating member 302 may be aligned with the lower surface of the semiconductor layer 214, or may be located at a height between the lower surface of the semiconductor layer 214 and the conductive layer 26.

The conductive layer 303 of the memory device 1E is provided on the insulating layers 301 and 330. The conductive layer 303 can have a portion provided on the insulating member 302 in the dummy area DAa and the peripheral area PR. The insulating layer 304, the insulating layer 305, and the insulating layer 306 are provided in this order on the insulating layers 301 and 330 and the conductive layer 303.

The pad unit PD in the sixth embodiment has a similar configuration to the pad unit PD described using FIG. 11 in the first embodiment. In the pad unit PD according to the sixth embodiment, neither the semiconductor layer 214, 216, nor 217, nor the conductive layer 218 is provided in an area overlapping with the via TV in the Z direction. That is, in the memory device 1E, a portion of the conductive layer 303 corresponding to the conductive portion MA where the surface is exposed through the via TV does not have a portion overlapping with the semiconductor layer 214, 216, or 217, or the conductive layer 218 in the Z direction. The configuration of the other parts of the memory device 1E according to the sixth embodiment is similar to that of the memory device 1 according to the first embodiment.

### <6-2> Manufacturing Method

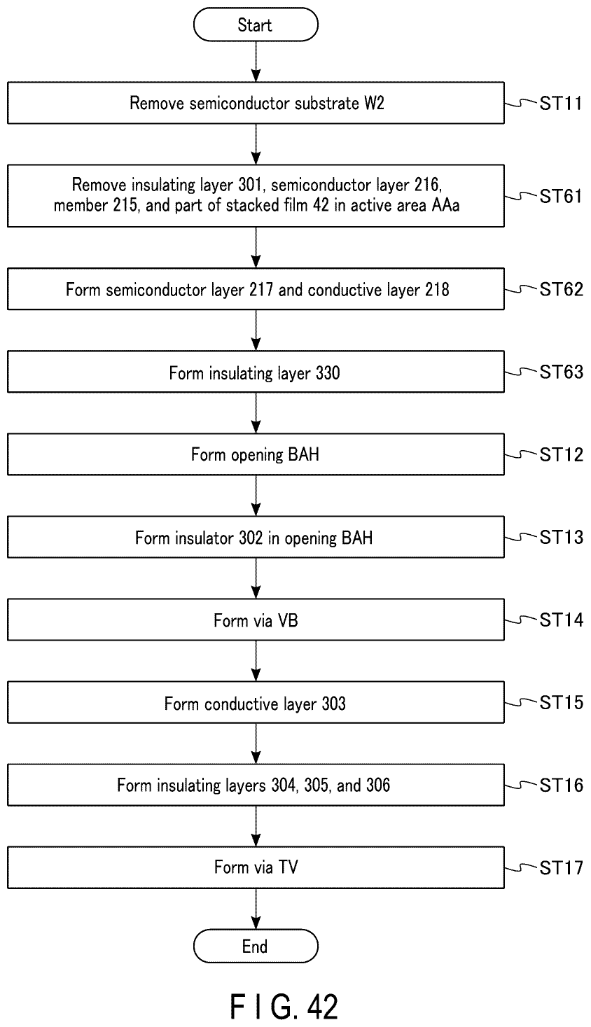

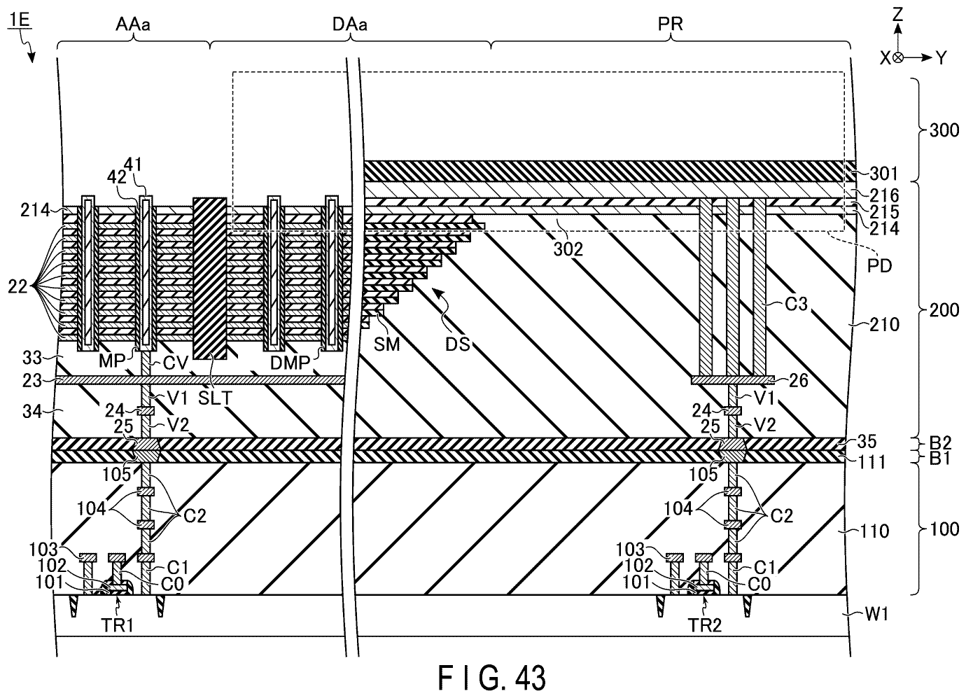

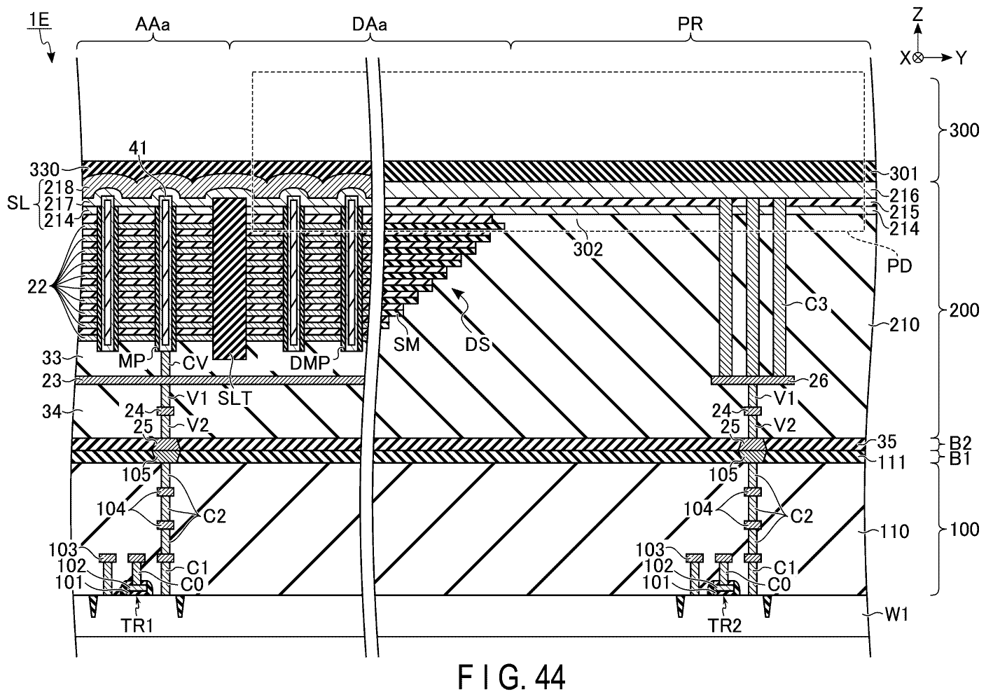

Next, as a method of manufacturing the memory device 1E according to the sixth embodiment, a method of forming the source line SL and the pad unit PD after bonding the semiconductor substrate W1 and the semiconductor substrate W2 is described with reference to FIG. 42 as appropriate. FIG. 42 is a flowchart showing an example of a method of manufacturing the memory device 1E according to the sixth embodiment. Each of FIGS. 43 and 44 is a cross-sectional view showing an example of a cross-sectional structure in the manufacturing process of the memory device 1E according to the sixth embodiment, and shows a cross section including an area in the vicinity of the pad unit PD.

First, like in the first embodiment, the semiconductor substrate W2 is removed (step ST11).

Next, as shown in FIG. 43, the insulating layer 301, the semiconductor layer 216, the member 215, and part of the stacked film 42 in the active area AAa are removed (step ST61). Specifically, first, a mask in which the portion of the active area AAa is opened is formed. Then, the insulating layer 301, the semiconductor layer 216, and the member 215 are removed in the opening of the mask by anisotropic etching processing. At this time, each of the member 215 and the semiconductor layer 214 can be used as an etching stopper layer. After that, for example, the stacked film 42 provided above the semiconductor layer 214 in the active area AAa is selectively removed by wet etching processing. In step ST61, the insulating layer 301, the semiconductor layer 216, the member 215, and part of the stacked film 42 in the dummy area DAa may be removed according to the shape of the mask used.

Next, a semiconductor layer 217 and a conductive layer 218 are formed (step ST62). Specifically, first, amorphous silicon corresponding to the semiconductor layer 217 is formed in a portion of the semiconductor layer 214 where the surface is exposed. Then, an impurity is introduced into the amorphous silicon formed as a film, and then heat treatment or the like is performed; thereby, the impurity is diffused to the semiconductor layers 214 and 217, and the amorphous silicon formed as a film is modified to polysilicon. Then, a conductive layer 218 is formed on the semiconductor layer 217. The conductive layer 218 contains, for example, at least one of tungsten, aluminum, titanium, and titanium nitride. In step ST62, at the time of heat treatment of modifying the semiconductor layer 217 to polysilicon, the semiconductor layers 214 and 216 are modified from amorphous silicon to polysilicon.

After that, as shown in FIG. 44, an insulating layer 330 is formed (step ST63). In step ST63, for example, first, an insulating layer 330 is formed on the conductive layer 218 and the insulating layer 301. Then, the upper surfaces of the insulating layers 330 and 301 are planarized by CMP processing or the like. In the present example, the insulating layer 330 formed on the insulating layer 301 is removed. The insulating layer 330 may remain on the upper surface of the insulating layer 301.

Then, like in the first embodiment, the pieces of processing of steps ST12 to ST17 are sequentially executed. Thereby, a structure corresponding to the source line SL and a structure corresponding to the pad unit PD shown in FIG. 41 are completed. Thus, the method of manufacturing the memory device 1E according to the sixth embodiment has a configuration in which, in the method of manufacturing the memory device 1 according to the first embodiment shown in FIG. 12, the processing of steps ST61, ST62, and ST63 is inserted between steps ST11 and ST12.

### <6-3> Advantageous Effects of the Sixth Embodiment

The memory device 1E according to the sixth embodiment has a structure in which the structure corresponding to the source line SL is removed in the dummy area DAa, and the dummy area DAa and the pad unit PD overlap in the Z direction. Therefore, like in the first embodiment, the memory device 1E according to the sixth embodiment can reduce the parasitic capacitance of the pad, and can reduce the chip size while suppressing degradation in interface speed.

### <7> Seventh Embodiment

A memory device 1F according to a seventh embodiment has a structure in which the pad unit PDa described in the second embodiment and the source line SL described in the sixth embodiment are combined. Details of the memory device 1F according to the seventh embodiment will now be described.

### <7-1> Configuration

The memory device 1F according to the seventh embodiment has a similar configuration to the memory device 1A according to the second embodiment except for the structure of the source line SL. A planar layout and a cross-sectional structure of a pad unit PDa in the memory device 1F according to the seventh embodiment will now be described.

### <7-1-1> Planar Layout of the Pad Unit PDa

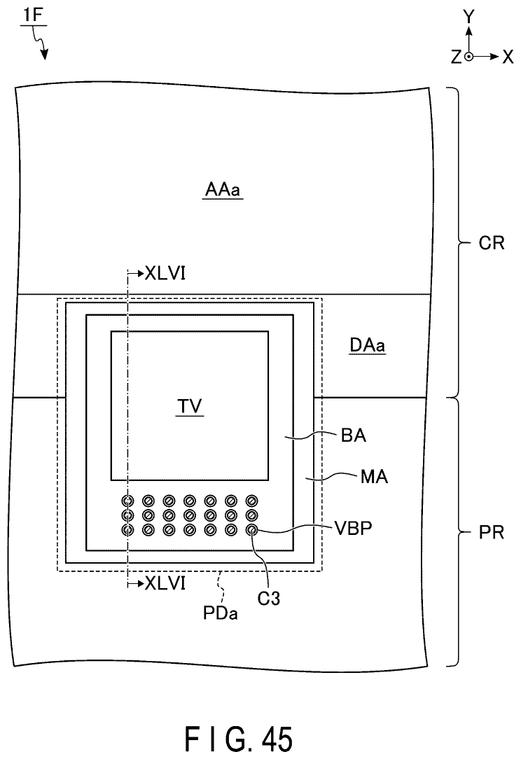

FIG. 45 is a plan view showing an example of a planar layout of the vicinity of the pad unit PDa in the memory device 1F according to the seventh embodiment. FIG. 45 shows a pad unit PDa used for connection to the input/output circuit 11, the logic controller 12, or the like in the memory device 1F, and part of each of the core area CR and the peripheral area PR.

As shown in FIG. 45, the memory device 1F has a configuration in which, in the memory device 1A according to the second embodiment, the active area AA and the dummy area DA of the core area CR are replaced with the active area AAa and the dummy area DAa of the sixth embodiment, respectively. The pad unit PDa of the seventh embodiment overlaps with each of the core area CR and the peripheral area PR. The pad unit PDa of the seventh embodiment has a portion overlapping with the dummy area DAa of the core area CR, and does not have a portion overlapping with the active area AAa. Similarly to the pad unit PDa of the second embodiment, the pad unit PDa of the seventh embodiment includes a conductive portion MA, an insulating portion BA, a via TV, and a plurality of contacts VBP.

### <7-1-2> Cross-Sectional Structure of the Pad Unit PDa

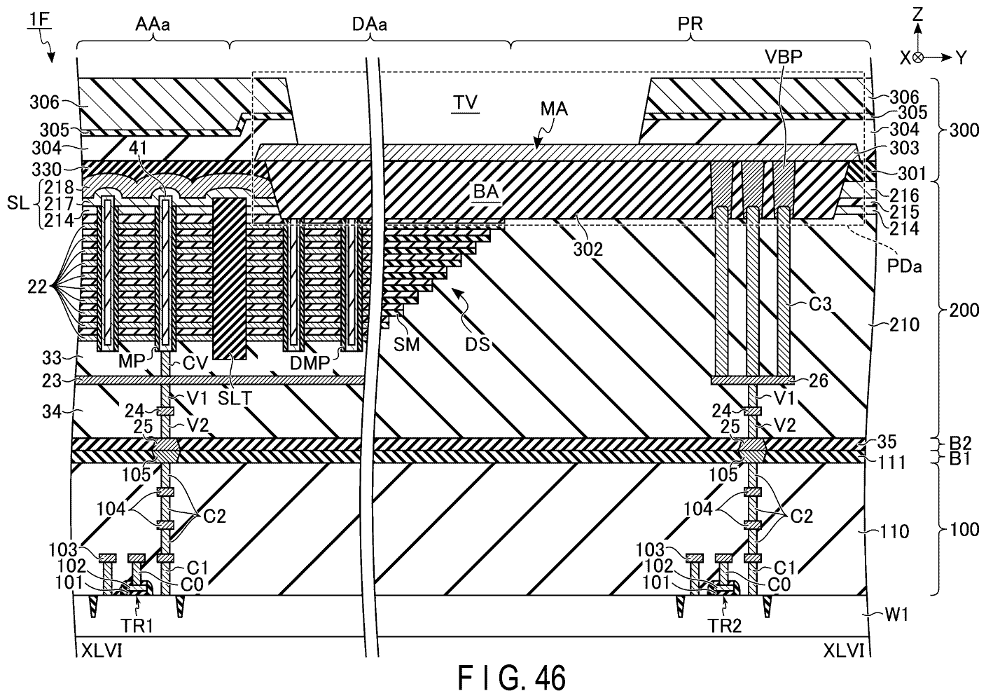

FIG. 46 is a cross-sectional view taken along line XLVI-XLVI of FIG. 45, showing an example of a cross-sectional structure of the vicinity of the pad unit PDa in the memory device 1F according to the seventh embodiment. As shown in FIG. 46, the memory device 1F has a structure in which the source line SL in the active area AAa and the dummy area DAa described using FIG. 41 in the sixth embodiment and the pad unit PDa described using FIG. 23 in the second embodiment are combined. The configuration of the other parts of the memory device 1F according to the seventh embodiment is similar to that of the memory device 1A according to the second embodiment.

### <7-2> Manufacturing Method

A method of manufacturing the memory device 1F according to the seventh embodiment is similar to a method in which, in the method of manufacturing the memory device 1A according to the second embodiment shown in FIG. 24, the processing of steps ST61, ST62, and ST63 shown in FIG. 42 is inserted between steps ST11 and ST12. That is, in the method of manufacturing the memory device 1F according to the seventh embodiment, a source line SL is formed after the removal of the semiconductor substrate W2 in a similar manner to the sixth embodiment, and then a structure corresponding to the pad unit PDa is formed in a similar manner to the second embodiment.

### <7-3> Advantageous Effects of the Seventh Embodiment

The memory device 1F according to the seventh embodiment has a structure in which the structure corresponding to the source line SL is removed in the dummy area DAa, and the dummy area DAa and the pad unit PDa overlap in the Z direction like in the sixth embodiment. Therefore, like in the sixth embodiment, the memory device 1F according to the seventh embodiment can reduce the parasitic capacitance of the pad, and can reduce the chip size while suppressing degradation in interface speed. Further, the memory device 1F according to the seventh embodiment can suppress the occurrence of defects that might occur due to level differences of the conductive portion MA, and can improve the yield like in the second embodiment.

### <8> Eighth Embodiment

A memory device 1G according to an eighth embodiment has a structure in which the pad unit PDb described in the third embodiment and the source line SL described in the sixth embodiment are combined. Details of the memory device 1G according to the eighth embodiment will now be described.

### <8-1> Configuration

The memory device 1G according to the eighth embodiment has a similar configuration to the memory device 1B according to the third embodiment except for the structure of the source line SL. A planar layout and a cross-sectional structure of a pad unit PDb in the memory device 1G according to the eighth embodiment will now be described.

### <8-1-1> Planar Layout of the Pad Unit PDb

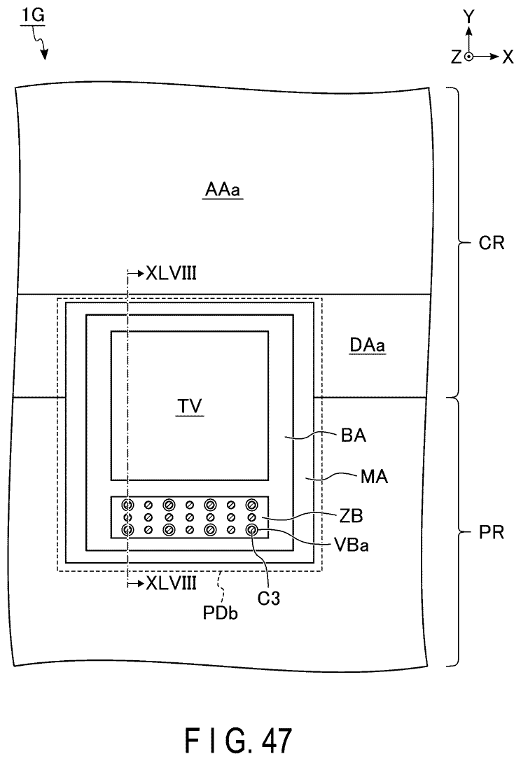

FIG. 47 is a plan view showing an example of a planar layout of the vicinity of the pad unit PDb in the memory device 1G according to the eighth embodiment. FIG. 47 shows a pad unit PDb used for connection to the input/output circuit 11, the logic controller 12, or the like in the memory device 1G, and part of each of the core area CR and the peripheral area PR.

As shown in FIG. 47, the memory device 1G has a configuration in which, in the memory device 1B according to the third embodiment, the active area AA and the dummy area DA of the core area CR are replaced with the active area AAa and the dummy area DAa of the sixth embodiment, respectively. The pad unit PDb of the eighth embodiment overlaps with each of the core area CR and the peripheral area PR. The pad unit PDb of the eighth embodiment has a portion overlapping with the dummy area DAa of the core area CR, and does not have a portion overlapping with the active area AAa. Similarly to the pad unit PDb of the third embodiment, the pad unit PDb of the eighth embodiment includes a conductive portion MA, an insulating portion BA, a via TV, a conductive portion ZB, and a plurality of vias VBa.

### <8-1-2> Cross-Sectional Structure of the Pad Unit PDb

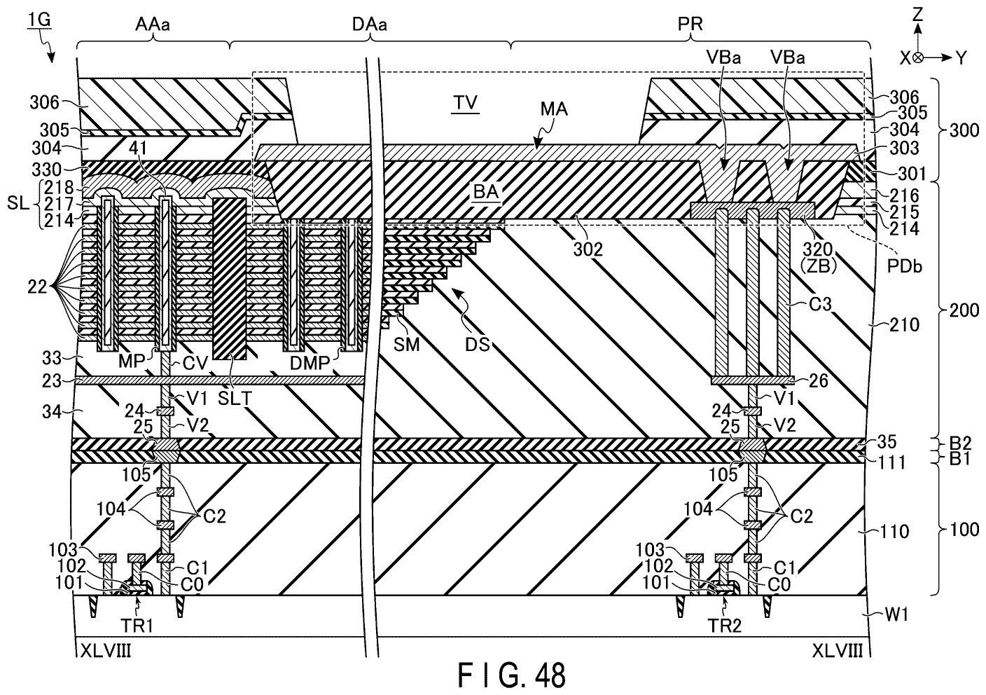

FIG. 48 is a cross-sectional view taken along line XLVIII-XLVIII of FIG. 47, showing an example of a cross-sectional structure of the vicinity of the pad unit PDb in the memory device 1G according to the eighth embodiment. As shown in FIG. 48, the memory device 1G has a structure in which the source line SL in the active area AAa and the dummy area DAa described using FIG. 41 in the sixth embodiment and the pad unit PDb described using FIG. 29 in the third embodiment are combined. The configuration of the other parts of the memory device 1G according to the eighth embodiment is similar to that of the memory device 1B according to the third embodiment.

<8-2> Manufacturing method

A method of manufacturing the memory device 1G according to the eighth embodiment is similar to a method in which, in the method of manufacturing the memory device 1B according to the third embodiment shown in FIG. 30, the processing of steps ST61, ST62, and ST63 shown in FIG. 42 is inserted between steps ST11 and ST12. That is, in the method of manufacturing the memory device 1G according to the eighth embodiment, a source line SL is formed after the removal of the semiconductor substrate W2 in a similar manner to the sixth embodiment, and then a structure corresponding to the pad unit PDb is formed in a similar manner to the third embodiment.

### <8-3> Advantageous Effects of the Eighth Embodiment

Like in the sixth embodiment, the memory device 1G according to the eighth embodiment has a structure in which the structure corresponding to the source line SL is removed in the dummy area DAa, and the dummy area DAa and the pad unit PDb overlap in the Z direction. Therefore, like in the sixth embodiment, the memory device 1G according to the eighth embodiment can reduce the parasitic capacitance of the pad, and can reduce the chip size while suppressing degradation in interface speed. Further, in the memory device 1G according to the eighth embodiment, the conductive portion MA and the contact C3 are connected to each other via the conductive portion ZB; thereby, the yield can be improved like in the third embodiment.

### <9> Ninth Embodiment

A memory device 1H according to a ninth embodiment has a structure in which the pad unit PDC described in the fourth embodiment and the source line SL described in the sixth embodiment are combined. Details of the memory device 1H according to the ninth embodiment will now be described.

### <9-1> Configuration

The memory device 1H according to the ninth embodiment has a similar configuration to the memory device 1C according to the fourth embodiment except for the structure of the source line SL. A planar layout and a cross-sectional structure of a pad unit PDc in the memory device 1H according to the ninth embodiment will now be described.

### <9-1-1> Planar Layout of the Pad Unit PDC

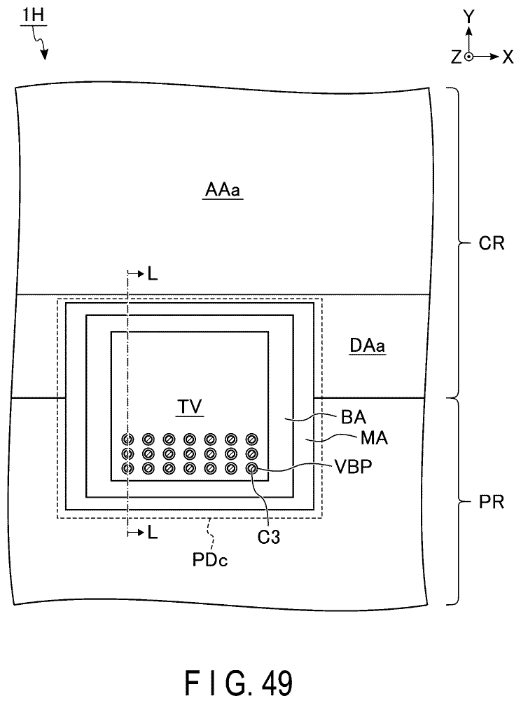

FIG. 49 is a plan view showing an example of a planar layout of the vicinity of the pad unit PDc in the memory device 1H according to the ninth embodiment. FIG. 49 shows a pad unit PDc used for connection to the input/output circuit 11, the logic controller 12, or the like in the memory device 1H, and part of each of the core area CR and the peripheral area PR.

As shown in FIG. 49, the memory device 1H has a configuration in which, in the memory device 1C according to the fourth embodiment, the active area AA and the dummy area DA of the core area CR are replaced with the active area AAa and the dummy area DAa of the sixth embodiment, respectively. The pad unit PDc of the ninth embodiment overlaps with each of the core area CR and the peripheral area PR. The pad unit PDc of the ninth embodiment has a portion overlapping with the dummy area DAa of the core area CR, and does not have a portion overlapping with the active area AAa. Similarly to the pad unit PDc of the fourth embodiment, the pad unit PDC of the ninth embodiment includes a conductive portion MA, an insulating portion BA, a via TV, and a plurality of contacts VBP.

### <9-1-2> Cross-Sectional Structure of the Pad Unit PDc

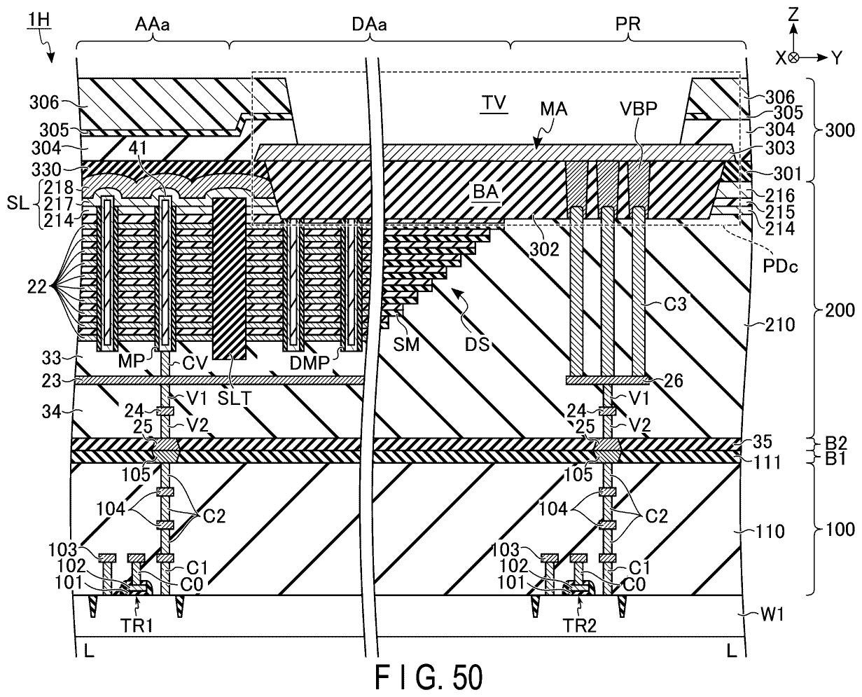

FIG. 50 is a cross-sectional view taken along line L-L of FIG. 49, showing an example of a cross-sectional structure of the vicinity of the pad unit PDc in the memory device 1H according to the ninth embodiment. As shown in FIG. 50, the memory device 1H has a structure in which the source line SL in the active area AAa and the dummy area DAa described using FIG. 41 in the sixth embodiment and the pad unit PDc described using FIG. 36 in the fourth embodiment are combined. The configuration of the other parts of the memory device 1H according to the ninth embodiment is similar to that of the memory device 1C according to the fourth embodiment.

### <9-2> Manufacturing Method

A method of manufacturing the memory device 1H according to the ninth embodiment is similar to a method in which, in the method of manufacturing the memory device 1C according to the fourth embodiment based on the method of manufacturing the memory device 1A according to the second embodiment shown in FIG. 24, the processing of steps ST61, ST62, and ST63 shown in FIG. 42 is inserted between steps ST11 and ST12. That is, in the method of manufacturing the memory device 1H according to the ninth embodiment, a source line SL is formed after the removal of the semiconductor substrate W2 in a similar manner to the sixth embodiment, and then a structure corresponding to the pad unit PDc is formed in a similar manner to the fourth embodiment.

### <9-3> Advantageous Effects of the Ninth Embodiment

Like in the sixth embodiment, the memory device 1H according to the ninth embodiment has a structure in which the structure corresponding to the source line SL is removed in the dummy area DAa, and the dummy area DAa and the pad unit PDc overlap in the Z direction. Therefore, like in the sixth embodiment, the memory device 1H according to the ninth embodiment can reduce the parasitic capacitance of the pad, and can reduce the chip size while suppressing degradation in interface speed. Further, in the memory device 1H according to the ninth embodiment, the via TV and the contacts VBP are arranged to overlap in the Z direction; thereby, the chip area can be suppressed like in the fourth embodiment.

### <10> Tenth Embodiment

A memory device 1I according to a tenth embodiment has a structure in which the pad unit PDd described in the fifth embodiment and the source line SL described in the sixth embodiment are combined. Details of the memory device 1I according to the tenth embodiment will now be described.

### <10-1> Configuration

The memory device 1I according to the tenth embodiment has a similar configuration to the memory device 1D according to the fifth embodiment except for the structure of the source line SL. A planar layout and a cross-sectional structure of a pad unit PDd in the memory device 1I according to the tenth embodiment will now be described.

### <10-1-1> Planar Layout of the Pad Unit PDd

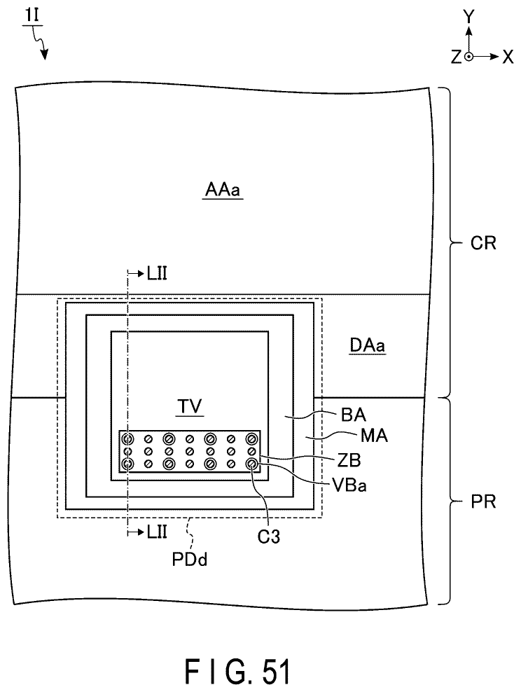

FIG. 51 is a plan view showing an example of a planar layout of the vicinity of the pad unit PDd in the memory device 1I according to the tenth embodiment. FIG. 51 shows a pad unit PDd used for connection to the input/output circuit 11, the logic controller 12, or the like in the memory device 1I, and part of each of the core area CR and the peripheral area PR.

As shown in FIG. 51, the memory device 1I has a configuration in which, in the memory device 1D according to the fifth embodiment, the active area AA and the dummy area DA of the core area CR are replaced with the active area AAa and the dummy area DAa of the sixth embodiment, respectively. The pad unit PDd of the tenth embodiment overlaps with each of the core area CR and the peripheral area PR. The pad unit PDd of the tenth embodiment has a portion overlapping with the dummy area DAa of the core area CR, and does not have a portion overlapping with the active area AAa. Similarly to the pad unit PDd of the fifth embodiment, the pad unit PDd of the tenth embodiment includes a conductive portion MA, an insulating portion BA, a via TV, a conductive portion ZB, and a plurality of vias VBa.

### <10-1-2> Cross-Sectional Structure of the Pad Unit PDd

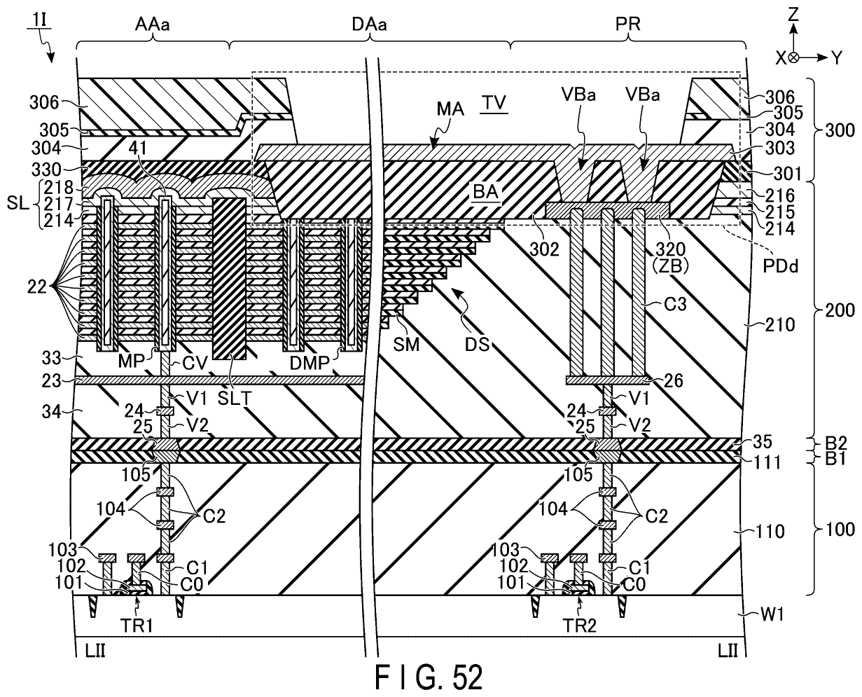

FIG. 52 is a cross-sectional view taken along line LII-LII of FIG. 51, showing an example of a cross-sectional structure of the vicinity of the pad unit PDd in the memory device 1I according to the tenth embodiment. As shown in FIG. 52, the memory device 1I has a structure in which the source lines SL in the active area AAa and the dummy area DAa described using FIG. 41 in the sixth embodiment and the pad unit PDd described using FIG. 38 in the fifth embodiment are combined. The configuration of the other parts of the memory device 1I according to the tenth embodiment is similar to that of the memory device 1D according to the fifth embodiment.

### <10-2> Manufacturing Method

A method of manufacturing the memory device 1I according to the tenth embodiment is similar to a method in which, in the method of manufacturing the memory device 1D according to the fifth embodiment based on the method of manufacturing the memory device 1B according to the third embodiment shown in FIG. 30, the processing of steps ST61, ST62, and ST63 shown in FIG. 42 is inserted between steps ST11 and ST12. That is, in the method of manufacturing the memory device 1I according to the tenth embodiment, a source line SL is formed after the removal of the semiconductor substrate W2 in a similar manner to the sixth embodiment, and then a structure corresponding to the pad unit PDd is formed in a similar manner to the fifth embodiment.

### <10-3> Advantageous Effects of the Tenth Embodiment

Like in the sixth embodiment, the memory device 1I according to the tenth embodiment has a structure in which the structure corresponding to the source line SL is removed in the dummy area DAa, and the dummy area DAa and the pad unit PDd overlap in the Z direction. Therefore, like in the sixth embodiment, the memory device 1I according to the tenth embodiment can reduce the parasitic capacitance of the pad, and can reduce the chip size while suppressing degradation in interface speed. Further, in the memory device 1I according to the tenth embodiment, the via TV and the conductive portion ZB are arranged to overlap in the Z direction; thereby, the chip area can be suppressed like in the fifth embodiment.

### <11> Eleventh Embodiment

A memory device 1J according to an eleventh embodiment has a structure in which, in the memory device 1 according to the first embodiment, the size in a planar view of the conductive portion MA of the pad unit PD is designed to be smaller than the size in a planar view of the insulating portion BA. Details of the memory device 1J according to the eleventh embodiment will now be described.

### <11-1> Configuration

The memory device 1J according to the eleventh embodiment has a similar configuration to the memory device 1 according to the first embodiment except for the structure of the pad unit PD. A planar layout and a cross-sectional structure of a pad unit PDe in the memory device 1J according to the eleventh embodiment will now be described.

### <11-1-1> Planar Layout of the Pad Unit PDe

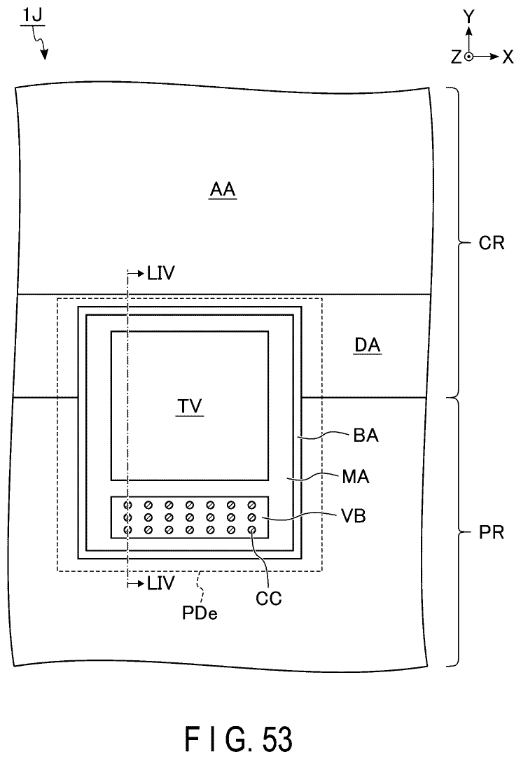

FIG. 53 is a plan view showing an example of a planar layout of the vicinity of the pad unit PDe in the memory device 1J according to the eleventh embodiment. FIG. 53 shows a pad unit PDe used for connection to the input/output circuit 11, the logic controller 12, or the like in the memory device 1J, and part of each of the core area CR and the peripheral area PR.

As shown in FIG. 53, the pad unit PDe overlaps with each of the core area CR and the peripheral area PR. The pad unit PDe has a portion overlapping with the dummy area DA of the core area CR, and does not have a portion overlapping with the active area AA. The pad unit PDe includes a conductive portion MA, an insulating portion BA, a via TV, and a via VB. The insulating portion BA is, for example, provided in a rectangular shape in a planar view. The outer edge of the insulating portion BA corresponds to the outer edge of the pad unit PDe. The conductive portion MA is, for example, provided in a rectangular shape in a planar view, and overlaps with the conductive portion MA. The outer edge of the conductive portion MA is located on the inside of the outer edge of the insulating portion BA. The configurations of the vias TV and VB in the pad unit PDe are similar to those of the vias TV and VB described in the first embodiment.

### <11-1-2> Cross-Sectional Structure of the Pad Unit PDe

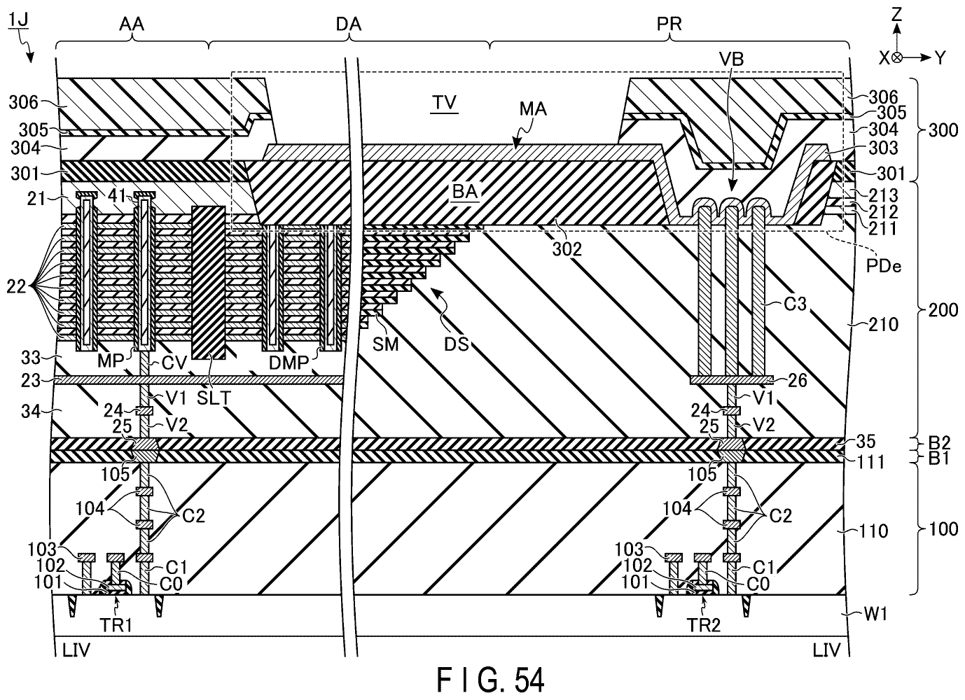

FIG. 54 is a cross-sectional view taken along line LIV-LIV of FIG. 53, showing an example of a cross-sectional structure of the vicinity of the pad unit PDe in the memory device 1J according to the eleventh embodiment. As shown in FIG. 54, the pad unit PDe has a configuration in which, in the pad unit PD described using FIG. 11 in the first embodiment, the outer edge of the conductive portion MA is placed on the inside of the outer edge of the insulating portion BA. Thus, the conductive layer 303 corresponding to the conductive portion MA does not have a portion overlapping with the conductive layer 21, 211, or 213 in the Z direction. The configuration of the other parts of the memory device 1J according to the eleventh embodiment is similar to that of the memory device 1 according to the first embodiment.

### <11-2> Manufacturing Method

A method of manufacturing the memory device 1J according to the eleventh embodiment is similar to a method in which, in the method of manufacturing the memory device 1 according to the first embodiment described using FIGS. 12 to 17, a change is made such that the conductive portion MA is placed on the inside of the insulating portion BA in a planar view.

### <11-3> Advantageous Effects of the Eleventh Embodiment

In the memory device 1J according to the eleventh embodiment, the area of the portion where the conductive portion MA and the source line SL face each other in the Z direction can be reduced more than in the first embodiment. As a result, the memory device 1J according to the eleventh embodiment can reduce the parasitic capacitance of the pad more than in the first embodiment, and can suppress deterioration in interface speed.

The aspect described in the eleventh embodiment may be combined with the second to tenth embodiments. That is, in each of the second to tenth embodiments, a configuration in which the outer edge of the conductive portion MA is located on the inside of the outer edge of the insulating portion BA is possible. As a result, the second to tenth embodiments can obtain similar effects to those of the eleventh embodiment.

### <12> Modification Examples and the Like

The memory device 1 described hereinabove can be variously modified.

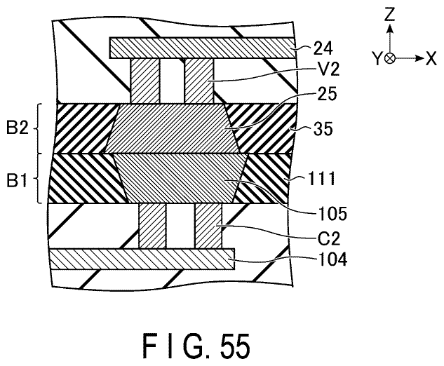

FIG. 55 is a cross-sectional view showing an example of a detailed cross-sectional structure of the vicinity of two bonding pads arranged to face each other in the memory device 1 according to the embodiments. FIG. 55 shows a conductive layer 105 (a bonding pad) formed using a semiconductor substrate W1 (not illustrated), a conductive layer 25 (a bonding pad) formed using a semiconductor substrate W2 (not illustrated), and some contacts C2 and V2 and conductive layers 104 and 24 connected to them. As shown in FIG. 55, the two bonding pads arranged to face each other can have different tapered shapes based on the etching direction during formation. Specifically, the conductive layer 105 formed using the semiconductor substrate W1 has, for example, an inverse tapered shape. The conductive layer 25 formed using the semiconductor substrate W2 has, for example, a tapered shape. Thus, in the shape of a cross section along the Z direction in a portion where the conductive layer 105 and the conductive layer 25 are joined, the side wall of the portion may not have a straight-lined shape but the portion may forms a non-rectangular shape in the cross section. Further, a set of two bonding pads arranged to face each other can be joined in a shifted manner according to alignment at the time of bonding processing. Therefore, a level difference can be formed between the side surface of the conductive layer 105 and the side surface of the conductive layer 25. A set of two bonding pads arranged to face each other may have a boundary, or may be integrated. A bonding pad and a contact C2 or V2 connected to the bonding pad may be integrally formed. To a bonding pad, a corresponding plurality of contacts C2 or V2 may be connected. For example, the conductive layer 105 may be connected to the conductive layer 104 via a plurality of contacts C2. Similarly, the conductive layer 25 may be connected to the conductive layer 24 via a plurality of contacts V2.

In the above embodiment, the memory device 1 may include a plurality of memory cell arrays 10. In a case where the memory device 1 includes a plurality of memory cell arrays 10, the memory device 1 can include a sense amplifier module 17 and a row decoder module 16 for each memory device 10. In this case, stacked wiring lines including a plurality of word lines WL are provided for each memory cell array 10. Then, a set of conductive layers 21, 211, and 213 corresponding to a source line SL or a set of semiconductor layers 214 and 217 and a conductive layer 218 corresponding to a source line SL is divided on a memory cell array 10 basis.

In the above embodiment, each of the circuit configuration, the planar layout, and the cross-sectional structure of the memory device 1 can be changed as appropriate. Other contacts may be inserted between the memory pillar MP and the conductive layer 23. Other contacts may be inserted between the contact C3 and the conductive layer 26. A conductive layer may be inserted into the coupled portion between contacts. The numbers of wiring layers and contacts included in the memory device 1 can be changed according to circuit design as appropriate. The memory pillar MP or each contact may have a tapered shape, an inverse tapered shape, or a bowing shape. The XY cross-sectional structure of the memory pillar MP may be a circular shape or an elliptical shape. Each wiring line in the stacked wiring lines may include a metal oxide film around a conductor such as tungsten. The conductive layer alternately stacked with the insulating layer in the stacked wiring lines may be regarded as a configuration including such a metal oxide film.

In the present specification, “connection” refers to being electrically connected, and does not exclude, for example, being connected via another element. “Electrically connected” may be connection via an insulator as long as operations similar to those in a case of being electrically connected can be performed. The “semiconductor substrate” may be referred to simply as a “substrate”. The “semiconductor layer” may be referred to as a “conductive layer”. The “area” may be regarded as a configuration included by a substrate. For example, in a case where it is provided that a semiconductor substrate W1 includes a storage area SA and a contact area CA, the storage area SA and the contact area CA are associated with different areas above the semiconductor substrate W1. The “height” corresponds to, for example, the spacing in the Z direction between a configuration of a measurement object and the semiconductor substrate W1. As a reference of “height”, a configuration other than the semiconductor substrate W1 may be used. The “planar view” corresponds to, for example, viewing the surface of the semiconductor substrate W1 from the vertical direction of the semiconductor substrate W1. The “via” may be referred to as an opening.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A memory device having a bonding surface, the memory device comprising:
a substrate having a first area and a second area arranged in a first direction;
a first circuit layer provided between the substrate and the bonding surface and including a CMOS circuit;
a second circuit layer provided above the bonding surface; and
a wiring layer provided above the second circuit layer, the wiring layer including a pad electrically connected to the CMOS circuit via the second circuit layer, wherein
the second circuit layer includes a layer stack and a plurality of first pillars, the layer stack including, in the first area, a plurality of first insulating layers and a plurality of first conductive layers alternately stacked in a second direction crossing the first direction and including, in the second area, the first insulating layers and the first conductive layers or a plurality of first members alternately stacked in the second direction, a material of the first members being different from both of materials of the first insulating layers and the first conductive layers, the first pillars, in the first area, penetrating the layer stack in the second direction and being electrically connected to a source line above the layer stack, and
the pad has a portion overlapping with the layer stack in the second direction and does not have a portion overlapping with the source line in the second direction.

2. The memory device according to claim 1, wherein
the layer stack has, in the second area, a layer stack portion in which the first insulating layers and the first members are alternately stacked in the second direction, and end portions of the stacked first members are provided in a staircase shape.

3. The memory device according to claim 1, wherein
the second circuit layer further includes, in the second area, a plurality of second pillars penetrating the layer stack in the second direction,
the first pillars are each configured to store data in portions crossing the first conductive layers, and the second pillars are not used to store data,
the pad has a portion overlapping with the second pillars in the second direction, and
the second pillars are electrically insulated from the source line.

4. The memory device according to claim 1, wherein
the pad is electrically connected to an interface circuit included in the CMOS circuit.

5. The memory device according to claim 1, wherein
the wiring layer includes a second conductive layer having a portion corresponding to the pad, and a second insulating layer provided to cover an upper portion of the second conductive layer, and
the second insulating layer has a first opening provided such that a surface of the second conductive layer is exposed in the portion corresponding to the pad.

6. The memory device according to claim 5, wherein
the wiring layer further includes an insulating member that insulates the source line and the second conductive layer from each other, and
the insulating member has, in the second area, a portion located at a same height as the source line and provided between the first opening and the layer stack.

7. The memory device according to claim 6, wherein
the substrate further has a third area provided to surround the first area and the second area in a planar view,
the second circuit layer further includes, in the third area, at least one first contact that has a portion provided at a same height as the layer stack and that is electrically connected to the CMOS circuit, and
the second conductive layer comprises, in the second area, a portion overlapping with the layer stack in the second direction and has, in the third area, a portion electrically connected to the at least one first contact.

8. The memory device according to claim 7, wherein
the insulating member has a second opening in a portion overlapping with the at least one first contact in the second direction, and
the second conductive layer, in the third area, is provided along the second opening and is connected to the at least one first contact in a bottom portion of the second opening.

9. The memory device according to claim 7, wherein
the wiring layer further includes at least one second contact penetrating the insulating member and individually connected to the at least one first contact, and
the second conductive layer is electrically connected to the at least one first contact via the at least one second contact.

10. The memory device according to claim 9, wherein
the first opening has a portion overlapping with the at least one second contact in the second direction.

11. The memory device according to claim 7, wherein
the wiring layer further includes a conductive member connected to the at least one first contact, an upper portion of the conductive member being covered with the insulating member, and
the insulating member has a third opening in a portion overlapping with the conductive member in the second direction, the second conductive layer filling the third opening and being connected to the conductive member in a bottom portion of the third opening.

12. The memory device according to claim 11, wherein
the first opening has a portion overlapping with the conductive member in the second direction.

13. The memory device according to claim 5, wherein
the substrate further has a third area provided to surround the first area and the second area in a planar view,
the second circuit layer further includes, in the third area, a first sublayer and a second sublayer provided in a same layer as the source line, the first sublayer containing, as a main component, a same material as at least part of the source line, the second sublayer being provided above the first sublayer via a second member, and
the first opening does not have a portion overlapping with the first sublayer or the second sublayer in the second direction.

14. The memory device according to claim 1, wherein
the second circuit layer further includes, in the first area, a third conductive layer used as part of the source line,
each of the first pillars includes a semiconductor layer extending in the second direction, and
the semiconductor layer and the third conductive layer are electrically connected to each other via a side surface of each of the first pillars.

15. The memory device according to claim 1, wherein
the wiring layer further includes, in the first area, a third conductive layer used as part of the source line,
each of the first pillars includes a semiconductor layer extending in the second direction, and
the third conductive layer has a portion provided along an upper portion of the semiconductor layer and is electrically connected to the semiconductor layer.

16. The memory device according to claim 1, further comprising:
a first pad provided adjacent to the bonding surface and electrically connected to the CMOS circuit; and
a second pad provided adjacent to the bonding surface and electrically connected between one of the first pillars and the first pad, wherein
a direction of a taper of the first pad and a direction of a taper of the second pad are different.

17. A memory device having a bonding surface, the memory device comprising:
a first circuit layer provided between a substrate and the bonding surface and including a CMOS circuit;
a second circuit layer provided above the first circuit layer via the bonding surface, the second circuit layer including a layer stack and a plurality of pillars, the layer stack including a plurality of first insulating layers and a plurality of first conductive layers alternately stacked in a stacking direction, each of the pillars extending in the stacking direction in the layer stack, the pillars including a first pillar electrically connected to a source line above the layer stack and configured to store data in portions crossing the first conductive layers and a second pillar not used to store data; and
a second conductive layer provided above the source line in the stacking direction, the second conductive layer including a portion corresponding to a pad and being electrically connected to the CMOS circuit, wherein
the second conductive layer has a portion overlapping with the second pillar in the stacking direction, the portion of the second conductive layer facing the second pillar in the stacking direction via an insulating member provided at a same height as the source line, without interposing the source line.

18. The memory device according to claim 17, wherein
the pad has a portion overlapping with the second pillar in the stacking direction, and does not have a portion overlapping with the source line in the stacking direction.

19. The memory device according to claim 18, further comprising:
a second insulating layer provided to cover an upper portion of the second conductive layer, wherein
the second insulating layer has a first opening provided such that a surface of the second conductive layer is exposed in the portion corresponding to the pad.

20. The memory device according to claim 17, wherein
the second circuit layer further includes a third insulating layer and at least one first contact electrically connected to the CMOS circuit, the third insulating layer being provided around the layer stack in a planar view, a portion of the at least first contact provided at a same height as the layer stack extending in the stacking direction in the third insulating layer, and
the second conductive layer further has a portion electrically connected to the at least one first contact.
